(19) United States
(12) Patent Application Publication
(10) Pub. No.: US 2018/0245205 A1
(43) Pub. Date: Aug. 30, 2018

(54) NANOPOROUS METAL-BASED FILM SUPPORTED ON AEROGEL SUBSTRATE AND METHODS FOR THE PREPARATION THEREOF

(71) Applicant: BAR-ILAN UNIVERSITY, Ramat Gan (IL)

(72) Inventors: Adi SALOMON, Tel Aviv (IL); Racheli RON, Holon (IL)

(73) Assignee: BAR-ILAN UNIVERSITY, Ramat Gan (IL)

(21) Appl. No.: 15/754,759

(22) PCT Filed: Aug. 22, 2016
(86) PCT No.: PCT/IL2016/050915

§ 371 Date: Feb. 23, 2018

Related U.S. Application Data
(60) Provisional application No. 62/208,846, filed on Aug. 24, 2015.

(51) Int. Cl. C23C 14/18; C04B 41/45; C04B 41/88; C04B 41/87; C04B 41/00; C04B 41/51; C04B 41/50; C01B 33/158; B82B 3/00; B82B 1/00; C23C 14/24; C23C 14/02; C23C 14/34

(52) U.S. Cl. CPC C23C 14/185; C23C 14/18; C04B 41/88; C04B 41/87; C04B 41/009; C04B 41/5116; C04B 41/5155; C04B 41/5049; C04B 41/5041; C01B 33/1585; B82B 3/008; B82B 1/005; C23C 14/24; C23C 14/021; C23C 14/34; C04B 41/4529

(57) ABSTRACT

Provided is a method for the fabrication of a nanoporous metal-based film. The method includes providing a ceramic aerogel substrate having a nanoporous structure. The substrate may include a bulk portion and a surface portion and the surface portion may be chemically or physically modified. The method may further include depositing a metal or a metal oxide from a deposition source on the ceramic aerogel substrate by a physical vapor deposition (PVD) process. The deposition may be performed at a power of less than about 90 W or at a current ranging from about 0.5 mA to about 100 mA. Further provided is a nanoporous metal-based film supported on a ceramic aerogel substrate having a nanoporous structure. The nanoporous structure of the aerogel defines the nanoporous structure of the metal-based film.

### FIELD OF THE INVENTION

The present invention is directed to nanoporous metal-based films supported on aerogel substrates and methods for the preparation thereof. The nanoporous films can be prepared by a large-scale, fast and cost-effective process from different types of metals and can be utilized in a variety of applications.

### BACKGROUND OF THE INVENTION

The field of nanoporous metals is driven by the desire to create materials with tunable electrical and optical properties. The most common directions for the preparation of nanoporous metals are dealloying, templating, and assembly of nano-sized metallic building-blocks into aerogels. There are additional methods such as nanosmelting or combustion synthesis.

Practically, all of the aforementioned strategies face a significant number of complications both in processing stages and products properties. For example, in templating techniques, difficulties arise at wetting and infiltration of metals or metals' precursors into the nanometer-sized interstitial regions within the templates. In dealloying techniques, an additional undesired material has to be incorporated with the desired metal into an alloy, which then has to be sacrificially eliminated. Consequently, complications, such as attaining both materials at the proper atomic-percent proportion in the alloy and at adequate mixing degrees (which determines pores characteristics) are evoked. Furthermore, all the current available preparation techniques are multistep and the resulting nanoporous metal contains foreign additives which eventually govern their properties and may deteriorate their performance (Kränzlin, N. and Niederberger, M., Mater. Horizons, 2015, 2, 359-377). When using templating techniques with sub-micron particles (such as metal-coated polystyrene (PS) or silica spheres) or metallic sol-gels for the preparation of nanoporous metals, nanoparticles' aggregation during casting or gelation constitute a critical hindrance for achieving a qualitative product, which might be a prominent technological impediment in large-scale fabrication.

Additional advanced fabrication techniques, which allow producing nanoporous reticulated metal structures having a thickness of maximum up to about a few micrometers are electron-beam lithography (EBL) and focused ion-beam (FIB) milling. While said techniques offer high-resolution and good reproducibility, the main drawbacks thereof include high cost, limited sample size and time-consuming process, which preclude the use of said techniques in the large-scale mass production.

In contrast, inexpensive techniques of metal deposition, such as, for example, physical vapor deposition (PVD), including, inter alia, sputtering and evaporation, are not known to provide nanoporous metallic films. Normally, PVD is used to form fine homogenous thin-films. A substance vapor is formed by either energetic collisions (sputtering) or heating until evaporation. Factors such as deposition parameters, surface morphology and surface chemistry determine the atoms mobility and the preferential nucleation sites (Wolf, S. and Tauber, R. N., Silicon Processing for the VLSI Era, Lattice Press, Sunset Beach, Calif., 1986). Typically, atoms condense on surfaces, growing into discrete islands which upon deposition fuse to form two-dimensional compact thin-film morphology. Even when using a porous substrate, PVD metal coatings are generally used to seal and/or protect such substrate. For example, US Patent Application Publication No. 2005/0089187 provides an electromagnetic transducer having a very low density diaphragm constructed of a nanoporous material such as aerogel or the like, wherein the aerogel may be provided with a skin of e.g. metal, plastic, or oxide to protect it. The outer skin may be formed by sputtering a suitable material onto the surface of the aerogel.

In another study, metals including Au, Pt, Cu, Al, Cr and Ti were deposited on silica aerogel films by vapor or sputter deposition processes. However, in order to obtain a patterned metal coating, appropriate masks in combination with photoresist methods had to be used [Hrubesh, L. W.; Poco, J. F., Conference: Fall meeting of the Materials Research Society (MRS), Boston, Mass. (United States), 28 Nov.-9 Dec. 1994].

There remains, therefore, an unmet need for a simple and inexpensive method for the preparation of nanoporous metals, which can conveniently be implemented in large-scale mass production.

### SUMMARY OF THE INVENTION

The present invention provides a method for the preparation of a nanoporous metal-based film supported on an aerogel substrate. Further provided are metal-based films, which can be supported on the aerogel substrates.

The present invention is based in part on the unexpected finding that a PVD technique can be utilized to prepare nanoporous metallic or metal oxide films. It has not been previously realized that a simple, inexpensive and abundant deposition technique can be utilized to provide three-dimensional (3D) large-scale metal-based nanoporous structures, which are highly sought after in a variety of applications. The method of the present invention comprises deposition of a metal or a metal oxide on an aerogel substrate, wherein the deposition can be performed, for example, by sputtering or evaporation. The inventors of the present invention have unexpectedly found that surface modification of an aerogel substrate in combination with the specific parameters of the PVD process, allow for the formation of nanoporous metallic structure, resembling that of a metallic aerogel. The nanoporous metal-based films prepared by the method of the present invention are transparent, conductive and lightweight. Additionally, the nanoporous metal-based films of the present invention are essentially free of foreign (e.g. sacrificial) metals. Structurally, said films can be defined by an inner nano-architecture of a three-dimensional network made of interconnected nano-sized ligaments and connective percolating (open-cell) nano-pores. The present invention, therefore, provides a rapid, non-expensive and large-scale method for the fabrication of low-density nanoporous metallic and metal-oxide products. Deposition of the nanoporous film can beneficially be performed in one step and on a large-scale. Additionally, it was surprisingly discovered that control over the nanostructure of the surface-modified aerogels and/or the deposition process parameters allows tuning of the metal-based films structural, electronic and optical properties. It was further found by the inventors of the present invention that aerogel substrates having a mean pore size of less than about 2 nm did not facilitate formation of the nanoporous metal-based films thereon.

Thus, in one aspect, the invention provides a method for the fabrication of a nanoporous metal-based film, the method comprising the steps of providing a ceramic aerogel substrate having a nanoporous structure, wherein the substrate comprises a bulk portion and a surface portion and wherein the surface portion is chemically or physically modified, and depositing a metal or a metal oxide from a deposition source on the ceramic aerogel substrate by a physical vapor deposition (PVD) process, wherein the deposition is performed at a power of less than about 90 W or at a current ranging from about 0.5 mA to about 100 mA, thereby obtaining a nanoporous metal-based film supported on the ceramic aerogel substrate.

According to some embodiments, the metal-based film comprises a metallic film or a metal oxide film. Each possibility represents a separate embodiment of the invention.

The ceramic aerogel can be formed from a material selected from a metalloid oxide, metal oxide, metal chalcogenide and combinations thereof. Each possibility represents a separate embodiment of the invention. In certain embodiments, the ceramic aerogel is formed from a material selected from the group consisting of silicon dioxide (silica, SiO₂), titanium dioxide (TiO₂), zirconium dioxide (ZrO₂), cadmium sulfide (CdS), cadmium selenide (CdSe), zirconium sulfide (ZnS), lead sulfide (PbS), and combinations thereof. Each possibility represents a separate embodiment of the invention. In some exemplary embodiments, the ceramic aerogel substrate is a silica-based substrate.

In some embodiments, the surface portion of the ceramic aerogel substrate includes surface atoms of the aerogel material. In some embodiments, the surface portion of the ceramic aerogel substrate has a thickness of from about 0.5 nm to about 100 nm.

The chemically modified surface portion of the ceramic substrate can include adsorbed molecules.

In some embodiments, the chemically modified surface portion includes one or more layers of adsorbed gaseous molecules or atoms. In certain such embodiments, the gaseous molecules or atoms are adsorbed on the surface atoms of the aerogel substrate. In some embodiments, the chemically modified surface portion includes pores, wherein at least about 20% of the pore volume is filled with gaseous molecules or atoms. In some embodiments the bulk portion of the substrate has pores, wherein at least 20% of the pore volume is filled with gaseous molecules or atoms.

In some embodiments, the composition of the gaseous molecules or atoms is different than the composition of air. In further embodiments, the gaseous molecules or atoms are selected from carbon dioxide (CO₂), nitrogen (N₂), argon (Ar) and combinations thereof. Each possibility represents a separate embodiment of the invention. In some exemplary embodiments, the gaseous molecules are CO₂.

According to some embodiments, the ceramic aerogel comprises less than about 5% of adsorbed water or water vapor relatively to the total weight of the aerogel. According to some embodiments, the surface portion of the ceramic aerogel is hydrophobic. According to certain embodiments, the chemically modified surface portion of the ceramic aerogel is hydrophobic. According to further embodiments, the ceramic aerogel is hydrophobic.

According to some embodiments, the ceramic aerogel substrate has a mean pore size ranging from about 2 nm to about 50 nm. According to certain embodiments, the surface portion of the ceramic aerogel substrate has a mean pore size ranging from about 2 nm to about 50 nm.

According to some embodiments, the step of providing the aerogel comprises preparation of an alcogel under a supersaturated alcoholic vapor atmosphere. According to some embodiments, the alcogel is prepared by a sol-gel process. In further embodiments, the sol-gel process comprises mixing an aerogel precursor material with a catalyst in a solvent, wherein the solvent comprises water and alcohol.

In further embodiments, the sol-gel process is performed under the supersaturated alcoholic vapor atmosphere for about 15 minutes.

In some embodiments, the step of providing the aerogel further comprises an alcogel suspension step, comprising placing the alcogel under a substantially anhydrous liquid. In certain embodiments, the alcogel suspension step further comprises holding the alcogel under the substantially anhydrous liquid for about 12 hours. The substantially anhydrous liquid can be selected from alcohols, including ethanol or methanol, and ketones, including acetone. Each possibility represents a separate embodiment of the invention.

In some embodiments, the step of providing the aerogel does not include ageing of the alcogel.

In various embodiments, the step of providing the aerogel further comprises supercritical drying of the alcogel. In further embodiments, the supercritical drying step comprises placing the alcogel into a critical point dryer (CPD) tank, which is substantially free of alcohol. In additional embodiments, the CPD tank is precooled to below about 5°-10° C. In further embodiments, the alcogel comprises a layer of the substantially anhydrous liquid on at least one surface thereof. In still further embodiments, the supercritical drying step further comprises filling the CPD tank with liquid CO₂. In yet further embodiments, the supercritical drying step further comprises gradually heating the CPD tank to a temperature of about 32-45° C. and maintaining said temperature for about 15 min. In still further embodiments, the CPD tank is held under pressure of from about 80 bar to about 100 bar.

According to various embodiments, the alcogel preparation step, the alcogel suspension step, and the supercritical drying step are performed in the same vessel.

According to some embodiments, the deposition of the metal is initiated within less than about 30 min minutes from the termination of the supercritical drying step.

According to some embodiments, the step of providing the aerogel comprises chemically modifying the surface portion thereof. In some embodiments, the chemically modified surface portion of the aerogel substrate includes one or more layers of adsorbed organic molecules. In certain such embodiments, the organic molecules are adsorbed on the surface atoms of the aerogel material. In certain embodiments, the chemically modified surface portion includes a monolayer of adsorbed organic molecules. The organic molecules can be selected from alkyls, organothiols and organosilanes. Each possibility represents a separate embodiment of the invention. In certain embodiments, the organic molecules include trimethylchlorosilane (TMCS) or methyltrimethoxysilane (MTMS). In further embodiments, the surface portion of the aerogel substrate is chemically modified by a technique selected from dipping, evaporation, self-assembled monolayers, Langmuir Blodgett, or a combination thereof. Each possibility represents a separate embodiment of the invention.

According to some embodiments, the step of providing the aerogel comprises physically modifying the surface portion thereof. In further embodiments, said step includes etching of the surface portion of the aerogel. In certain such embodiments, the physically modified surface portion of the aerogel substrate includes an etched surface. The etching can be performed by a technique selected from dry etching, wet chemical etching or a combination thereof. In some embodiments, dry etching includes ion beam etching. According to further embodiments, the etching is performed for at least about 1 minute. According to some embodiments, the deposition of the metal is initiated within less than about 30 minutes from the termination of the etching procedure.

According to some embodiments, the step of providing the ceramic aerogel comprises adsorption of organic molecules on the surface portion of the ceramic aerogel substrate, the bulk portion of the aerogel or both. In some related embodiments, the organic molecules used for adsorption as described above are selected form the group consisting of alkyls, organothiols, organosilanes and combinations thereof. In a currently preferred embodiment, the organic molecules comprise trimethylchlorosilane (TMCS). In a related embodiment, the adsorption of the organic molecules as described above is performed before the supercritical drying step.

According to some embodiments, the method includes depositing a metal or a metal oxide on the surface portion of the ceramic aerogel substrate.

In various embodiments, the metal is selected from the group consisting of Au, Ag, Pt, Al, Cu, Ti, Fe and combinations thereof. In additional embodiments, the metal comprises a metal alloy, selected from the group consisting of Au/Ag, Au/Fe, Au/Cu, Au/Ag/Cu, Au/Al, Au/Pt, Au/Ti, Au/Ag/Al, Au/Ag/Cu/Pt, Au/Ag/Cu/Al, Au/Ag/Cu/Ti, Pt/Ag, Pt/Cu, Cu/Al, Cu/Ag, Pt/Fe, Pt/Al, Pt/Ag/Cu, Pt/Au/Cu/Ti, Ag/Fe, Cu/Fe, Ti/Fe and Pt/Au/Al. Each possibility represents a separate embodiment of the invention.

In various embodiments, the metal oxide is selected from the group consisting of CuO, CuO₂, AgO, AgO₂, TiO₂, Al₂O₃, and combinations thereof. Each possibility represents a separate embodiment of the invention.

In some embodiments the deposition is performed at a power of less than about 90 W. In some embodiments, the deposition is performed at a current ranging from about 0.5 mA to about 100 mA. In some embodiments the deposition is performed at a power of less than about 90 W and a current ranging from about 0.5 mA to about 100 mA.

According to various embodiments, the PVD process is selected from sputter deposition or evaporative deposition. Each possibility represents a separate embodiment of the invention.

In certain embodiments, the PVD process is sputter deposition. In further embodiments, the deposition source comprises a plasma source and a metal or a metal oxide target. In still further embodiments, the plasma source operates at a power of lower than about 90 W during the deposition step. In yet further embodiments, the plasma source operates at a power of lower than about 75 W during the deposition step. In some embodiments, the plasma source operates at a beam energy of from about 5 keV to about 15 keV. In some embodiments, the plasma source operates at a current of about 0.5-40 mA. In some embodiments, the sputter deposition continues for up to about 10 minutes. In still further embodiments, the sputter deposition continues for up to about 5 minutes.

In some exemplary embodiments, the sputter deposition comprises a preliminary step of the plasma source ignition, during which the aerogel substrate is not exposed to the plasma source. In some embodiments, the sputter deposition process is performed with an inert sputtering gas. In some embodiments, the sputter deposition process is performed with a reactive sputtering gas. The reactive gas can include oxygen (O₂).

In certain embodiments, the PVD process is an evaporative deposition. In further embodiments, the deposition source comprises a metal or a metal oxide source and an energy source that evaporates the metal or metal oxide. In still further embodiments, the energy source operates at a current ranging from about 0.5 mA to about 100 mA. In yet further embodiments, the energy source operates at a current ranging from about 1 mA to about 100 mA. In yet further embodiments, the evaporative deposition continues for up to about 20 minutes.

According to some currently preferred embodiments, the method of the present invention does not include templating. In further embodiments, the method does not include application of a mask to the ceramic aerogel substrate. In yet further embodiments, the method does not include dealloying. In still further embodiments, the method does not include electron and/or ion beam milling.

According to some embodiments, the method further comprises a step of separating the metal-based film from the ceramic aerogel substrate. The step of separating the metal-based film from the ceramic aerogel substrate can be performed by dry etching, wet chemical etching, cutting, pealing or any combination thereof.

In another aspect, there is provided a nanoporous metal-based film, prepared according to the method of the present invention. In some embodiments, the nanoporous metal-based film is supported on a ceramic aerogel substrate.

In some embodiments, the nanoporous metal-based film comprises a metal selected from the group consisting of Au, Ag, Pt, Al, Cu, Ti, Fe and combinations thereof. In additional embodiments, the metal comprises a metal alloy, selected from the group consisting of Au/Ag, Au/Fe, Au/Cu, Au/Ag/Cu, Au/Al, Au/Pt, Au/Ti, Au/Ag/Al, Au/Ag/Cu/Pt, Au/Ag/Cu/Al, Au/Ag/Cu/Ti, Pt/Ag, Pt/Cu, Cu/Al, Cu/Ag, Pt/Fe, Pt/Al, Pt/Ag/Cu, Pt/Au/Cu/Ti, Ag/Fe, Cu/Fe, Ti/Fe and Pt/Au/Al. Each possibility represents a separate embodiment of the invention.

In further embodiments, the metal-based film comprises a metal oxide selected from the group consisting of CuO, CuO₂, AgO, AgO₂, TiO₂, Al₂O₃, and combinations thereof. In other embodiments, the metal-based film comprises a metal nitride. Each possibility represents a separate embodiment of the invention.

In some embodiments, the nanoporous metal-based film has a thickness ranging from about 1 nm to about 500 m. In some embodiments, the nanoporous metal-based film has a mean pore size ranging from about 50 nm to about 500 nm. In certain embodiments, the nanoporous metal-based film has a substantially uniform pore distribution. In some embodiments, the nanoporous metal-based film has pores which are bimodal in size. In further embodiments, the nanoporous metal-based film comprises interconnected ligaments having a mean thickness ranging from about 5 nm to about 300 nm.

In further embodiments, the nanoporous metal or metal oxide film is for use in energy storage systems, energy supply systems, hydrogen storage systems, sensors, optics, optoelectronics, catalysis or any combination thereof. Each possibility represents a separate embodiment of the invention.

In another aspect, the present invention provides a nanoporous metal-based film supported on a ceramic aerogel substrate having a nanoporous structure and an electrostatic surface, wherein the nanoporous structure and an electrostatic surface of the aerogel define the nanoporous structure of the metal-based film. In some embodiments, the metal-based film has a purity of at least about 98% wt. In some embodiments, the metal based film of the invention is three dimensional isotropic.

The ceramic aerogel can be formed from a material selected from a metalloid oxide, metal oxide, metal chalcogenide and combinations thereof. Each possibility represents a separate embodiment of the invention. In certain embodiments, the ceramic aerogel is formed from a material selected from the group consisting of silicon dioxide (silica, SiO₂), titanium dioxide (TiO₂), zirconium dioxide (ZrO₂), cadmium sulfide (CdS), cadmium selenide (CdSe), zirconium sulfide (ZnS), lead sulfide (PbS), and combinations thereof. Each possibility represents a separate embodiment of the invention. In some exemplary embodiments, the ceramic aerogel substrate is a silica-based substrate.

In some embodiments, the ceramic aerogel substrate has a mean pore size ranging from about 2 nm to about 50 nm.

In some embodiments, the nanoporous metal-based film comprises a metal selected from the group consisting of Au, Ag, Pt, Al, Cu, Ti, Fe and combinations thereof. In additional embodiments, the metal comprises a metal alloy, selected from the group consisting of Au/Ag, Au/Fe, Au/Cu, Au/Ag/Cu, Au/Al, Au/Pt, Au/Ti, Au/Ag/Al, Au/Ag/Cu/Pt, Au/Ag/Cu/Al, Au/Ag/Cu/Ti, Pt/Ag, Pt/Cu, Cu/Al, Cu/Ag, Pt/Fe, Pt/Al, Pt/Ag/Cu, Pt/Au/Cu/Ti, Ag/Fe, Cu/Fe, Ti/Fe and Pt/Au/Al. Each possibility represents a separate embodiment of the invention.

In further embodiments, the metal-based film comprises a metal oxide selected from the group consisting of CuO, CuO₂, AgO, AgO₂, TiO₂, Al₂O₃, and combinations thereof. In other embodiments, the metal-based film comprises a metal nitride. Each possibility represents a separate embodiment of the invention.

In some embodiments, the nanoporous metal-based film has a thickness ranging from about 1 nm to about 500 μm. In some embodiments, the nanoporous metal-based film has a mean pore size ranging from about 50 nm to about 500 nm. In certain embodiments, the nanoporous metal-based film has a substantially uniform pore distribution. In further embodiments, the nanoporous metal-based film comprises interconnected ligaments having a mean thickness ranging from about 5 nm to about 300 nm. In some other embodiments, the pores of the nanoporous metal-based film as described above are bimodal in size.

According to some embodiments, the nanoporous metal-based film is transparent in the visible, near-IR and ultra-violet (UV) spectra region. According to some embodiments, the nanoporous structure of the ceramic aerogel defines the optical properties and/or the electronic properties of the metal-based film. Each possibility represents a separate embodiment of the invention.

According to some embodiments, the nanoporous metal-based film is fabricated by depositing a metal or metal oxide on the ceramic aerogel substrate by a PVD process.

In further embodiments, the nanoporous metal-based film is for use in energy storage systems, energy supply systems, hydrogen storage systems, sensors, optics, optoelectronics, catalysis or any combination thereof. Each possibility represents a separate embodiment of the invention.

Further embodiments and the full scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1A: Schematic representation of the ceramic aerogel substrate having a bulk portion and a surface portion.

FIG. 1B: Schematic representation of the ceramic aerogel substrate having an adsorbed layer of gaseous molecules, wherein the gaseous molecules are adsorbed onto the surface portion of the aerogel substrate.

FIG. 1C: Schematic representation of the ceramic aerogel substrate having an adsorbed and absorbed layer of gaseous molecules, wherein the gaseous molecules are adsorbed onto and absorbed into the pores of the surface portion of the aerogel substrate.

FIG. 1D: Schematic representation of the ceramic aerogel substrate having an adsorbed and absorbed layer of gaseous molecules, wherein the gaseous molecules are adsorbed onto and absorbed into the pores of the surface portion and absorbed into the pores of the bulk portion of the aerogel substrate.

FIG. 2A: Schematic representation of the nanostructure of the metal-based nanoporous film supported on the ceramic aerogel substrate.

FIGS. 2B-2C: High resolution scanning electron microscope (HR-SEM) images of the cross-section of the gold nanoporous film supported on the SiO₂-aerogel at magnification of 25,000 (FIG. 2B) and of the silver nanoporous film supported on the SiO₂-aerogel at magnification of 32,500 (FIG. 2C). The cross-section was obtained by applying a platinum layer on top of the Au and Ag nanoporous films and cutting the metal layers and the aerogel by focus ion beam (FIB).

FIG. 3: High resolution scanning electron microscope (HR-SEM) image of SiO₂-aerogel at magnification of 106,000 (106 k). The inset shows a photograph of a thin transparent silica aerogel substrate inside aluminum holder after supercritical drying.

FIG. 4: Photographs of the silver, aluminum and gold metallic films (2nd column) as compared to the bulk-metal colors (3rd column). 4th column shows fabricated gold transparent films which exhibit different colors.

FIG. 5: High resolution scanning electron microscope (HR-SEM) images of highly porous transparent gold film on top of a silica aerogel substrate at magnification of 20,000 and 50,000 (inset).

FIGS. 6A-6C: High resolution scanning electron microscope (HR-SEM) images of nanoporous metallic films which are made of silver (FIG. 6A, magnification 130,000), gold (FIG. 6B, magnification 250,000) and aluminum (FIG. 6C, magnification 120,000).

FIGS. 7A-7D: SEM and HR-SEM images of different metallic nanoporous films: silver (FIG. 7A—SEM, magnification of 50 k and 7B—SEM, magnification of 130 k), platinum (FIG. 7C—SEM, magnification of 150 k) and copper (FIG. 7D—HR-SEM, magnification of 20 k).

FIGS. 8A-8B: High- and low-magnification SEM images of an Au film: magnification of 160 k (FIG. 8A) and magnification of 65 k (FIG. 8B).

FIGS. 9A-9B: SEM images of two silver films at magnification of 20K, in which the nanostructure of each networks is prominently different due to the different solvent contents during the synthesis of the silica aerogel.

FIGS. 10A-10C: High resolution scanning electron microscope (HR-SEM) images of nanoporous silver films deposited on a silica aerogel which underwent surface etching at magnification of 20 k (FIG. 10A), 12 k (FIG. 10B) and 20 k (FIG. 10C).

FIGS. 11A-11B: Elemental analyses of gold nanoporous film: Energy dispersive X-ray spectroscopy (EDS) (FIG. 11A) and grazing-incident X-ray diffraction (GIXRD) (FIG. 11B).

FIG. 12: Optical transmission spectra of a transparent Au thin-film (curve A) and two different transparent Au nanoporous films prepared according to the method of the present invention (curve B—prepared on an aerogel substrate with a larger mean pore size and curveC-prepared on an aerogel substrate with a smaller mean pore size).

FIG. 13: SEM image of the Au nanoporous film modified with focused ion-beam (FIB) milling.

FIGS. 14A-14B: SEM and HR-SEM images of silver (FIG. 14A, SEM) and copper (FIG. 14B, HR-SEM) films deposited on glass substrate (left inset) instead of aerogel substrate (two right insets).

FIG. 15: SEM image of the Ag film deposited on a silica aerogel, which was not efficiently protected after the supercritical drying process.

FIGS. 16A-16B: SEM images of the Ag film prepared under high dc power (100 W) (FIG. 16A) and by an elongated sputtering time of 15 min (FIG. 16B).

FIGS. 17A-17B: SEM images of the Au film prepared under different ion beam energy. Three dimensional networks formed under 10 keV (FIG. 17A) and three dimensional networks formed under 4 keV (FIG. 17B).

FIGS. 18A-18B: HR-SEM images of Au film demonstrating a gritty texture taken at magnification of 120 k (FIG. 18A) and 250 k (FIG. 18B).

FIGS. 19A-19B: Cross-sectional SEM images of simultaneously prepared gold network depicted by the letter B on top of silica aerogel substrate depicted by the latter C in FIG. 19A, and a dense gold film depicted by the letter B on top of glass slide depicted by the letter C in FIG. 19B. The latter A depicts a platinum layer in both FIGS. 19A and 19B.

FIGS. 20A-20B: Cross-sectional SEM images of simultaneously prepared silver network depicted by the letter B on top of silica aerogel substrate depicted by the latter C in FIG. 20A, and a dense silver film depicted by the letter B on top of glass slide depicted by the letter C in FIG. 20B. The latter A depicts a platinum layer in both FIGS. 20A and 20B.

FIGS. 21A-21B: Light transmission spectra of nanoporous metal-based film compared with a dense metal film. Light transmission of nanoporous networks depicted in solid line and light transmission of dense films is depicted in dashed line for gold (Au) (FIG. 21A) and silver (Ag) (FIG. 21B).

FIGS. 22A-22B: Optical photographs of water droplets with high contact angle on top of hydrophobic silica aerogel (FIG. 21A), and on top of silver network which was deposited on hydrophobic silica aerogel (FIG. 21B).

FIGS. 23A-23B: Optical photographs of a nanoporous silver-based film (FIG. 23A) and a free-standing nanoporous silver film after to the removal of the silica aerogel substrate (FIG. 23B).

FIGS. 24A-24B: Optical photographs of a flexible free-standing nanoporous silver film in a folded state between two tweezers (FIG. 24A) and after the folding in a flat state (FIG. 24B).

FIGS. 25A-25B: SEM images of metallic nanoporous films, the scale bar is 100 nm. 25A depicts platinum (Pt) based nanoporous film in a magnification of 200 k and 25B depicts iron (Fe) based nanoporous film in a magnification of 160K.

FIGS. 26A-26B: Time-dependent work function (WF) data measured for a gold-based nanoporous film (FIG. 26A) and silver-based nanoporous film (FIG. 26B) in the dark, while illuminating the sample and under increasing light intensity.

FIG. 27A-27B: Raman scattering spectra of C₆₀ molecules generated by employing a silver-based nanopourous film as a substrate (FIG. 27A) and the deconvolution of the pentagonal band Ag(2) demonstrating the different shifts of different reduction levels of the C₆₀ molecules (FIG. 27B).

FIG. 28: cathodoluminescence (CL) spectra of silver nanoporous film (bottom panel), silica aerogel (middle panel) and dense silver film (top panel).

FIG. 29: SEM image of a ZnO network prepared by sputtering using an argon beam with an energy of 10 keV and an intensity of 614 μA.

FIGS. 30A-30B: HR-SEM image of Titania (TiO₂) NETAL. low×5,000 (FIG. 30A); and high-magnifications×20000 (FIG. 30B).

FIG. 31: HR-SEM image of a network nanostructure made of TiO2.×15000

### DETAILED DESCRIPTION OF THE INVENTION

The present invention provides nanoporous metal-based films supported on ceramic aerogel substrates and methods of the fabrication of said nanoporous films. The method of the present invention provides the benefit of an inexpensive, large-scale, convenient and rapid fabrication process, which can be utilized on a variety of aerogel substrates of different shapes and types. The shape and size of the nanoporous metal-based film are determined by the dimensions of the aerogel substrate, such that complex film geometries and shapes of the film can be produced with relative ease. The nanoporous metal film obtainable by the method of the present invention can comprise various metals, metal alloys or metal oxides, having extremely high surface area and ultralow density, particularly as compared to their bulk counterparts. Furthermore, the purity of the obtained metal-based films can be easily controlled.

The present invention is based in part on the unexpected finding that physical vapor deposition technique, which is extensively used in the field of metal-based coatings, can be utilized to prepare nanoporous metallic or metal oxide films. The method of the present invention includes deposition of a metal or a metal oxide on a ceramic aerogel substrate, wherein the deposition can be performed, for example, by sputter deposition or evaporative deposition. The inventors of the present invention have unexpectedly discovered that surface modification of an aerogel substrate allows for the formation of nanoporous metal-based structure, resembling that of a metallic aerogel. Modification of the aerogel can be performed, inter alia, to increase hydrophobicity of the surface and/or the bulk of the aerogel. It was found by the inventors of the present invention that the modified aerogel substrate has a strong electrostatic nature. Additionally, it was found that decrease in the mean pore size of the ceramic aerogels prevented formation of the nanoporous metal-based structures. Without wishing to being bound by theory or mechanism of action, it can be assumed that the surface modification of the ceramic aerogel substrate provides, inter alia, the specific morphology (e.g. mean pore size) or the electrostatic surface, which is sufficient for the formation of the nanoporous metal-based films. Said unique surface of aerogel induces self-organization of the coalesced atoms into a disordered 3D network with nanosize building-blocks, yet scalable Furthermore, utilizing operation conditions which are less energetic than typical conditions of a physical vapor deposition process are prerequisite for obtaining the desired nanoporous structure of the metal-based film. The fabrication method of the present invention obviates the need for using an external sacrificial material, for prefabrication of nanoparticles and the assembly thereof into a macroscopic nanoporous metal material, or for templating processes, which are typically employed in the currently-known metal aerogel preparation processes.

The nanoporous films prepared by the method of the present invention are transparent, conductive and lightweight. Structurally, said films can be defined by having an inner nano-architecture of a three-dimensional network made of interconnected nano-sized ligaments and connective percolating (open-cell) nano-pores. The nanostructure of the metal-based film is dependent on the nanostructure of the ceramic aerogel. Thus, the present invention further provides metal-based films supported on the aerogel substrate, wherein the structure of the film is defined by the structure of the aerogel substrate. The ceramic aerogel substrate can be used to conveniently handle the nanoporous metal-based film. Alternatively, the nanoporous film can be detached from the aerogel substrate by a variety of conventional techniques.

In one aspect, the invention provides a method for the fabrication of a nanoporous metal-based film, the method comprising the steps of providing a ceramic aerogel substrate having a nanoporous structure, wherein the substrate comprises a bulk portion and a surface portion and wherein the surface portion is chemically or physically modified; and depositing a metal or metal oxide from a deposition source on the ceramic aerogel substrate by a physical vapor deposition (PVD) process thereby obtaining a nanoporous metal-based film supported on the ceramic aerogel substrate.

The term “nanoporous,” as used herein, refers to an open pore structure, wherein the pores have a mean width (diameter) of up to about 500 nm.

The term “aerogel”, as used herein, refers to a solid synthetic porous material derived from a gel.

Ceramic Aerogel Substrate

According to some embodiments, the step of providing a ceramic aerogel substrate having a nanoporous structure, the substrate comprising a bulk portion and a surface portion, wherein the surface portion is chemically or physically modified, includes synthesizing the aerogel by methods known in the art and chemically or physically modifying the surface portion of the substrate. In other embodiments, said step includes a new and/or modified method of the aerogel preparation, which provides an aerogel substrate having a modified surface portion.

The ceramic aerogel can be formed from different materials and types of materials. The non-limiting examples of the materials suitable for forming the ceramic aerogel substrate include metalloid oxides, metal oxides, metal chalcogenides, and combinations thereof. Metalloid oxides can include, inter alia, silicon dioxide (silica, SiO₂). Metal oxides can include, among others, titanium dioxide (titania, TiO₂) and zirconium dioxide (zirconia, ZrO₂). Chalcogenides are chemical compounds consisting of at least one chalcogen anion and at least one more electropositive element. In some embodiments, the chalcogenides are selected from sulfides and selenides. The non-limiting examples of metal chalcogenides include cadmium sulfide (CdS), cadmium selenide (CdSe), zirconium sulfide (ZnS), lead sulfide (PbS), and combinations thereof. In some exemplary embodiments, the ceramic aerogel substrate is a silica-based substrate.

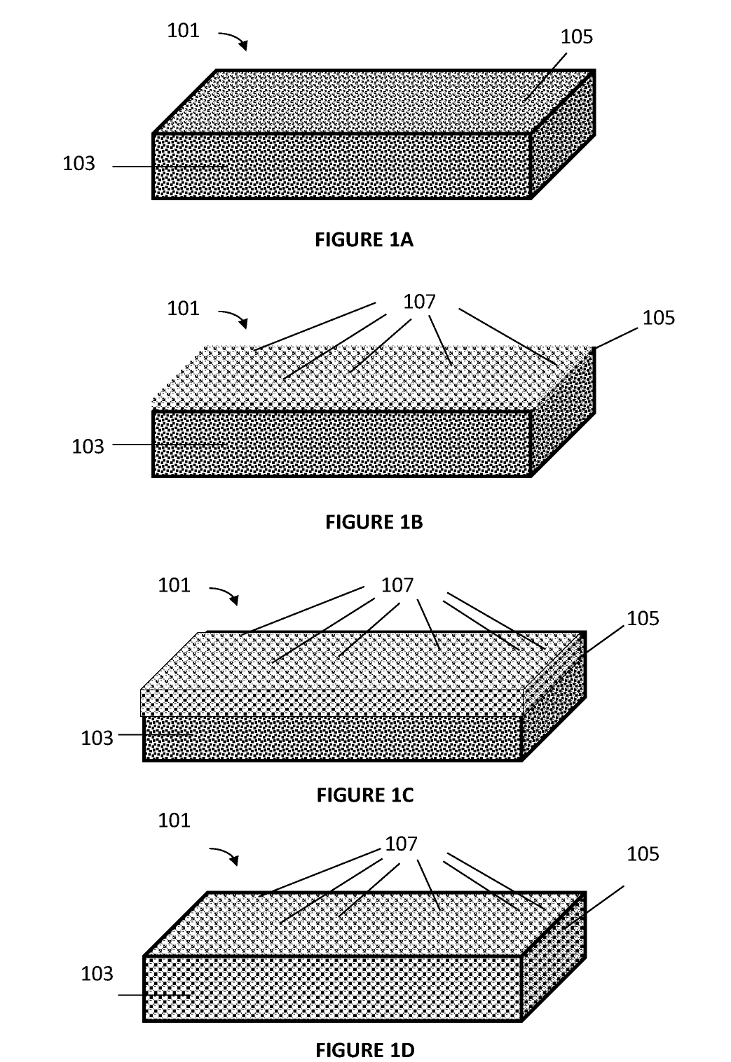

A ceramic aerogel substrate is schematically shown in FIG. 1A, in accordance with some embodiments of the invention. As mentioned hereinabove, aerogel substrate 101 has bulk portion 103 and surface portion 105. A person skilled in the art will readily realize that since the aerogel generally takes the shape of the mold in which it is prepared, the aerogel can be made in any possible shape and a variety of sizes. The non-limiting examples of the aerogel substrate shape include rectangular, cubic, cylindrical, spherical or semi-spherical shape. In some embodiments, the ceramic aerogel has a rectangular shape, as presented in FIG. 1A. The thickness of the ceramic aerogel substrate can range from about 10 nm to about 30 cm or more. In some exemplary embodiments, the geometrical surface area of the ceramic aerogel substrate can range from about 1 nm² to about 8000 mm². The term “geometrical surface area”, as used herein, refers to a two-dimensional outer surface area of the aerogel substrate and does not include the surface area of the pores.

In some embodiments, the ceramic aerogel substrate includes more than one surface portion, wherein the surface portion is chemically or physically modified. For example, the aerogel substrate can have a top and a bottom modified surface portions.

In some embodiments, the surface portion of the ceramic aerogel substrate includes surface atoms of the aerogel material. In some embodiments, the surface portion of the ceramic aerogel substrate has a thickness of from about 0.5 to about 100 nm. In further embodiments, the surface portion of the ceramic aerogel substrate has a thickness of from about 0.5 to about 50 nm, of from about 0.5 to about 25 nm, of from about 0.5 to about 10 nm, of from about 1 to about 50 nm, or of from about 10 to about 25 nm. Each possibility represents a separate embodiment of the invention.

The chemically modified surface portion of the ceramic substrate can include adsorbed or absorbed molecules or atoms. Each possibility represents a separate embodiment of the invention.

A ceramic aerogel substrate having an adsorbed layer of gaseous molecules, according to some embodiments of the invention, is schematically shown in FIG. 1B. In certain such embodiments, surface portion 105 is a top surface of aerogel substrate 101. A plurality of gaseous molecules 107 is adsorbed onto surface portion 105.

A ceramic aerogel substrate having adsorbed and absorbed gaseous molecules, according to some embodiments of the invention, is schematically shown in FIG. 1C. Surface portion 105 includes several atomic layers of aerogel substrate 101. A plurality of gaseous molecules 107 is adsorbed onto and absorbed into the pores of surface portion 105.

In some embodiments, the bulk portion of the ceramic aerogel substrate is modified. A ceramic aerogel substrate having adsorbed and absorbed gaseous molecules, according to some embodiments of the invention, is schematically shown in FIG. 1D. A plurality of gaseous molecules 107 is adsorbed onto and absorbed into the pores of surface portion 105, as well as into the pores of bulk portion 103.

In some embodiments, the chemically modified surface portion includes one or more layers of adsorbed gaseous molecules. In certain such embodiments, the gaseous molecules are adsorbed on the surface atoms of the aerogel material.

In some embodiments, the chemically modified surface portion includes pores, wherein at least about 20% of the pore volume of the surface portion is filled with gaseous molecules or atoms. In further embodiments, at least about 30% of the pore volume is filled with gaseous molecules or atoms, at least about 40%, at least about 50%, at least about 60%, at least about 70%, or at least about 80%. Each possibility represents a separate embodiment of the invention. The surface portion can have a thickness of from about 0.5 to about 100 nm, of from about 0.5 to about 50 nm, of from about 0.5 to about 25 nm, of from about 0.5 to about 10 nm, of from about 1 to about 50 nm, or of from about 10 to about 25 nm. Each possibility represents a separate embodiment of the invention.

In some embodiments the bulk portion of the substrate has pores, wherein at least 20% of the pore volume of the bulk portion is filled with gaseous molecules or atoms. In further embodiments, at least about 30% of the pore volume is filled with gaseous molecules or atoms, at least about 40%, at least about 50%, at least about 60%, at least about 70%, or at least about 80%. Each possibility represents a separate embodiment of the invention.

In some embodiments, the composition of the gaseous molecules or atoms is different than the composition of air. In further embodiments, the gaseous molecules or atoms are selected from carbon dioxide (CO₂), nitrogen (N₂), argon (Ar) and combinations thereof. Each possibility represents a separate embodiment of the invention. In some exemplary embodiments, the gaseous molecules are CO₂.

In certain embodiments, at least about 20% of the pore volume of the surface portion of the aerogel substrate is filled with carbon dioxide. In certain embodiments, at least about 30% of the pore volume of the surface portion of the aerogel substrate is filled with carbon dioxide. In further embodiments, at least about 40% of the pore volume is filled with carbon dioxide, at least about 50%, at least about 60%, at least about 70% or at least about 80%. Each possibility represents a separate embodiment of the invention.

In certain embodiments, at least about 20% of the pore volume of the bulk portion of the aerogel substrate is filled with carbon dioxide. In certain embodiments, at least about 30% of the pore volume of the bulk portion of the aerogel substrate is filled with carbon dioxide. In further embodiments, at least about 40% of the pore volume is filled with carbon dioxide, at least about 50%, at least about 60%, at least about 70% or at least about 80%. Each possibility represents a separate embodiment of the invention.

According to some embodiments, the chemically modified surface portion is hydrophobic. In some embodiments the hydrophobic silica gives rise to contact angle values of between about 90 to about 135 degrees. In some related embodiments, the hydrophobic metal network deposited on hydrophobic silica give rise to contact angle values of between about 30 to about 80 degrees. Thus, according to some embodiments, the ceramic aerogel comprises less than about 10% of adsorbed water or water vapor relatively to the total weight of the aerogel. In further embodiments, the ceramic aerogel comprises less than about 7% of adsorbed water or water vapor. In yet further embodiments, the ceramic aerogel comprises less than about 5% of adsorbed water or water vapor. In still further embodiments, the ceramic aerogel comprises less than about 4% of adsorbed water or water vapor. In yet further embodiments, the ceramic aerogel comprises less than about 3% of adsorbed water or water vapor. In still further embodiments, the ceramic aerogel comprises less than about 2% of adsorbed water or water vapor. It has been found by the inventors of the present invention that the ceramic aerogel substrates, which experienced shrinkage as a result of the ambient humidity sorption and therefore a reduction in the mean pore sizes thereof, did not allow formation of a nanoporous metal-based film thereon by the methods of the present invention.

According to some embodiments, the ceramic aerogel substrate has a mean pore size ranging from about 2 nm to about 50 nm. According to some embodiments, the ceramic aerogel substrate has a mean pore size ranging from about 5 nm to about 40 nm, from about 10 nm to about 50 nm, from about 10 nm to about 40 nm, from about 20 nm to about 50 nm, from about 30 nm to about 50 nm, or from about 10 nm to about 30 nm. Each possibility represents a separate embodiment of the invention. The term “mean pore size”, as used in various embodiments of the invention, refers to the size of a pore in the largest dimension thereof.

According to some embodiments, the surface portion of the ceramic aerogel substrate has a mean pore size ranging from about 2 nm to about 50 nm. According to some embodiments, the surface portion has a mean pore size ranging from about 5 nm to about 40 nm, from about 10 nm to about 50 nm, from about 10 nm to about 40 nm, from about 20 nm to about 50 nm, from about 30 nm to about 50 nm, or from about 10 nm to about 30 nm. Each possibility represents a separate embodiment of the invention.

According to further embodiments, the surface modification of the ceramic aerogel substrate provides a surface portion which has a mean pore size ranging from about 2 nm to about 50 nm. According to some embodiments, the surface modification provides a surface portion which has a mean pore size ranging from about 5 nm to about 40 nm, from about 10 nm to about 50 nm, from about 10 nm to about 40 nm, from about 20 nm to about 50 nm, from about 30 nm to about 50 nm, or from about 10 nm to about 30 nm. Each possibility represents a separate embodiment of the invention.

According to some embodiments, the bulk portion of the ceramic aerogel substrate has a mean pore size ranging from about 2 nm to about 50 nm. According to some embodiments, the bulk portion has a mean pore size ranging from about 5 nm to about 40 nm, from about 10 nm to about 50 nm, from about 10 nm to about 40 nm, from about 20 nm to about 50 nm, from about 30 nm to about 50 nm, or from about 10 nm to about 30 nm. Each possibility represents a separate embodiment of the invention.

According to some embodiments, the bulk portion of the ceramic aerogel substrate has substantially the same mean pore size as the surface portion. According to further embodiments, the mean pore size of the bulk portion and of the surface portion of the substrate varies by no more than 20%. In yet further embodiments, the mean pore size varies by no more than 15%, 10%, or even 5%. In certain embodiments, the mean pore size of the surface portion is larger than the mean pore size of the bulk portion.

The pore size of the aerogel substrate can be measured by various techniques, as known in the art, for example, electron microscopy, Gas sorption porosimetry (BET, BJH), He pycnometry, or SAXS (small-angle x-ray scattering). Each possibility represents a separate embodiment of the invention.

According to some embodiments, the surface portion of the ceramic aerogel substrate is electrostatic. According to some additional embodiments, the bulk portion of the ceramic aerogel substrate is electrostatic.

Preparation of a Ceramic Aerogel Substrate Having a Chemically Modified Surface Portion

In some embodiments, the step of providing the aerogel having a nanoporous structure, the substrate comprising a bulk portion and a surface portion, wherein the surface portion is chemically or physically modified, comprises preparing the aerogel by a modified preparation technique. According to further embodiments, the step of providing the aerogel comprises preparation of an alcogel under a supersaturated alcoholic vapor atmosphere, preferably wherein said step does not include aging of the aerogel. The term “alcogel”, as used herein, refers to an intermediate product of the aerogel, having a solid structure comprising pores filled with alcohol.

The alcogel is prepared by a sol-gel process, as known in the art, including hydrolysis and polycondensation of an aerogel precursor material in the presence of a catalyst. The non-limiting examples of suitable alcogel precursors include tetraethoxysilane (tetraethyl orthosilicate) (Si(OC₂H₅)₄, TEOS), tetramethoxysilane (tetramethyl orthosilicate) (Si(OCH₃)₄, TMOS), aluminum alkoxides, zirconium alkoxides, and titanium n-propoxide. The suitable catalysts can include ammonium hydroxide or ammonium fluoride.

The sol-gel process is performed in a solvent, wherein the solvent includes water and alcohol or ketone. The non-limiting examples of suitable alcohols include ethanol and methanol. Typically, ethanol is used with a TEOS precursor and methanol is used with a TMOS precursor. The ketone can include acetone.

According to some embodiments of the invention, the sol-gel process is performed under a supersaturated alcoholic vapor atmosphere. In certain embodiments, the mixture of the aerogel precursor, catalyst and solvent is held under the supersaturated alcoholic vapor atmosphere for about 15 minutes. The product of the reaction mixture is termed herein “alcogel”. It has been found by the inventors of the present invention that substantially shorter or longer gelation times did not provide the desired modification of the surface portion, which allowed for the formation of the nanoporous metal-based film on the aerogel substrate.

The customary alcogel preparation procedure includes an aging step of the alcogel, including a week-long suspension of the alcogel, while daily renewing the solvent in the reactor.

In contrast to said typical alcogel preparation procedure, in some exemplary embodiments, the step of providing the aerogel does not include ageing of the alcogel.

In some embodiments, the step of providing the aerogel further comprises a modified alcogel suspension step, comprising placing the alcogel under a substantially anhydrous liquid. The term “substantially anhydrous liquid”, as used herein, refers in some embodiments to a liquid, which contains less than about 1% w/w water. In further embodiments, the term refers to a liquid, which contains less than about 0.5% w/w water, less than about 0.1% w/w water, less than about 0.05% w/w water or less than about 0.01 w/w water. Each possibility represents a separate embodiment of the invention. The substantially anhydrous liquid can be selected from alcohols, including ethanol or methanol, and ketones, including acetone. In certain embodiments, the alcogel suspension step further comprises holding the alcogel under the substantially anhydrous liquid for from about 10 to about 14 hours. In some exemplary embodiments, the alcogel is held under the substantially anhydrous liquid for about 12 hours. It has been found by the inventors of the present invention that substantially shorter or longer suspension times did not provide the desired modification of the surface portion, which allowed for the formation of the nanoporous metal-based film on the aerogel substrate.

In various embodiments, the step of providing the aerogel further comprises supercritical drying of the alcogel. In further embodiments, the supercritical drying step comprises placing the alcogel into a critical point dryer (CPD) tank. Preferably, the CPD tank has a protective cover to reduce the aerogel substrate damage during supercritical drying. Thus, according to some embodiments, the alcogel is covered by a protective cover during the supercritical drying step.

In some embodiments, the CPD tank is precooled to below about 10° C. prior to placing the alcogel therein. In further embodiments, the CPD tank is precooled to below about 7° C. In further embodiments, the CPD tank is precooled to below about 5° C.

In some embodiments, the CPD tank is substantially free of alcohol. The term “substantially free of alcohol”, as used herein, refers in some embodiments to a CPD tank, which contains less than about 10% alcohol relatively to the volume of the CPD tank. In further embodiments, the term “substantially free of alcohol, refers to a CPD tank, which contains less than about 5% alcohol or less thank about 2.5% alcohol relatively to the volume of the CPD tank.

In further embodiments, the alcogel comprises a layer of the substantially anhydrous liquid on at least one surface thereof. In certain embodiments, the layer of the substantially anhydrous liquid is adsorbed on the surface of the alcogel. The thickness of the layer can range from about 0.01 mm to about 0.5 mm. In further embodiments, the thickness of the anhydrous liquid layer ranges from about 0.05 mm to about 0.25 mm.

In still further embodiments, the supercritical drying step further comprises filling the CPD tank with liquid gas. The liquid gas can include any substance, which can be formed into a supercritical fluid. The non-limiting examples of such substances include CO₂, Ar, H₂O, SF₆, methane, ethane, propane, hexane, isopropanol and ethanol. Each possibility represents a separate embodiment of the invention. In some exemplary embodiments, the liquid gas is CO₂.

In some embodiments, the alcogel is suspended under the liquid gas atmosphere for up to about 10 minutes. In further embodiments, the alcogel is suspended under the liquid gas atmosphere for about 6 minutes. The liquid gas can be gently stirred in the CPD tank. In some exemplary embodiments, the liquid gas is stirred for about 3 minutes.

In yet further embodiments, the liquid gas in the CPD tank is exchanged with a fresh portion of the liquid gas. In some embodiments, the alcogel is suspended under the fresh portion of the liquid gas atmosphere for up to about 10 minutes. In further embodiments, the alcogel is suspended under the liquid gas atmosphere for about 6 minutes. The liquid gas can be gently stirred in the CPD tank. In some exemplary embodiments, the liquid gas is stirred for about 3 minutes.

In some embodiments, the liquid gas in the CPD tank is exchanged with a fresh portion of the liquid gas for at least about four times. In further embodiments, the liquid gas in the CPD tank is exchanged with a fresh portion of the liquid gas for at least about five times. In still further embodiments, the liquid gas in the CPD tank is exchanged with a fresh portion of the liquid gas for at least about six times. In some exemplary embodiments, the liquid gas in the CPD tank is exchanged with a fresh portion of the liquid gas for seven times.

In yet further embodiments, the supercritical drying step further comprises gradually heating the CPD tank to a temperature of about 30° C.-50° C. In certain embodiments, the CPD tank is heated to a temperature of 32° C.-45° C. In further embodiments, said temperature is maintained for about 15 min. In still further embodiments, the CPD tank is held under pressure of from about 80 bar to about 100 bar. In yet further embodiments, the CPD tank is depressurized until ambient pressure is reached. In some embodiments, the CPD tank is depressurized at the rate of about 50 psi/min to about 150 psi/min. In certain embodiments, the CPD tank is depressurized at the rate of about 100 psi/min.

According to various embodiments, the alcogel preparation step, the alcogel suspension step, and the supercritical drying step are performed in the same vessel.

According to some embodiments, the deposition of the metal is initiated within less than about 60 minutes from the termination of the supercritical drying step. According to some embodiments, the deposition of the metal is initiated within less than about 50 minutes from the termination of the supercritical drying step, less than about 40 minutes, less than about 30 minutes, less than about 20 minutes, or less than about 10 minutes. Each possibility represents a separate embodiment of the invention. Without wishing to being bound by theory or mechanism of action, the indicated relatively short time period between the supercritical drying step termination and the metal or metal oxide deposition, decreases diffusion of the gas out of the aerogel and increases the amount of gas trapped in the aerogel nanostructure. Accordingly, the indicated period of time allows for the formation of modified surface portion, and optionally, bulk portion, of the aerogel substrate.

Without further wishing to being bound by theory or mechanism of action, it is contemplated that the modified preparation method of the aerogel provides an aerogel substrate, wherein at least about 20% of the pore volume of the surface portion of the substrate is filled with gaseous molecules or atoms. It is further contemplated that the modified preparation method of the aerogel provides an aerogel substrate, wherein at least about 30% of the pore volume of the surface portion of the substrate is filled with gaseous molecules or atoms. In further embodiments, at least about 40% of the pore volume is filled with gaseous molecules or atoms, at least about 50%, at least about 60%, at least about 70% or at least about 80%. Each possibility represents a separate embodiment of the invention. In further embodiments, the gaseous molecules include CO₂.

Chemical and Physical Modification of the Surface Portion of a Ceramic Aerogel Substrate

The ceramic aerogel substrate can be prepared according to the methods known in the art, and further be subjected to a surface modification procedure. For example, a silica-based aerogel can be prepared by a method selected from a base-catalyzed TEOS procedure, base-catalyzed TMOS procedure or subcritically-dried trimethylchlorosilane (TMCS) procedure. TiO₂-based aerogels can be prepared by a sol-gel method using Ti(IV)-isopropoxide as a precursor, anhydrous ethanol, water, and nitric acid. Additional information on the preparation of ceramic aerogels can be found at www.aerogels.org; Sol-gel synthesis of non-silica monolithic materials. Materials. 3(4), 2815-2833, Mohanan, J. L., Arachchige, I. U., & Brock, S. L. (2005); Porous semiconductor chalcogenide aerogels. Science, 307(5708), 397-400, Bag, S., Trikalitis, P. N., Chupas, P. J., Armatas, G. S., & Kanatzidis, M. G. (2007); and Porous semiconducting gels and aerogels from chalcogenide clusters. Science, 317(5837), 490-493.

The surface modification of the ceramic aerogel substrate can include chemical or physical modification. Each possibility represents a separate embodiment of the invention. In some embodiments, the chemically or physically modified surface portion is electrostatic.

In some embodiments, the step of providing the aerogel having a nanoporous structure, wherein the substrate comprises a bulk portion and a surface portion and wherein the surface portion is chemically or physically modified, comprises chemically modifying the surface portion of the aerogel substrate.

In further embodiments, the method of the chemical modification of the ceramic aerogel surface portion includes adsorption of gaseous molecules or atoms. The gaseous molecules or atoms can be selected from, but not limited to, CO₂, N₂ or Ar, on the surface portion of the ceramic aerogel substrate. In yet further embodiments, the method of the chemical modification of the ceramic aerogel surface portion includes adsorption and absorption of gaseous molecules or atoms on the surface portion and in the pores of the ceramic aerogel substrate. The non-limiting example of adsorbing gaseous molecules includes suspension of the ceramic aerogel substrate in a saturated gas atmosphere in a closed chamber for at least about 1 hour.

In further embodiments, the method of the chemical modification of the ceramic aerogel surface portion and/or bulk portion includes adsorption of organic molecules, such as, but not limited to, alkyls, organothiols, organosilanes and combination thereof, on the surface portion of the ceramic aerogel substrate, the bulk portion of the aerogel or both. Each possibility represents a separate embodiment of the invention. In a related embodiment, the adsorption of the organic molecules as described above is performed before the supercritical drying step.

An “alkyl” group refers to a saturated aliphatic hydrocarbon, including straight-chain, branched-chain and cyclic alkyl groups. Alkyl can include 1-12 carbons, 2-6 carbons, 2-4 carbons, or 3-24. Alkyl may be unsubstituted or substituted by one or more groups selected from alcohol, ketone, aldehyde, halogen, carbonate, carboxylate, carboxylic acid, acyl, amido, amide, amine, imine, ester, ether, cyano, nitro, and azido. Each possibility represents a separate embodiment of the present invention.

The non-limiting examples of organothiols include alkylthiols, arylthiols, alkylarylthiols, alkenyl thiols, alkynyl thiols, cycloalkyl thiols, heterocyclyl thiols, heteroaryl thiols, alkylthiolates, alkenyl thiolates, alkynyl thiolates, cycloalkyl thiolates, heterocyclyl thiolates, heteroaryl thiolates, ω-functionalized alkanethiolates, arenethiolates, and combinations thereof. The non-limiting examples of organosilanes include alkylsilanes, arylsilanes, alkylarylsilanes, alkenyl silanes, alkynyl silanes, cycloalkyl silanes, heterocyclyl silanes, heteroaryl silanes, and combinations thereof. Organothiol and/or organosilane may be unsubstituted or substituted by one or more groups selected from alcohol, ketone, aldehyde, halogen, carbonate, carboxylate, carboxylic acid, acyl, amido, amide, amine, imine, ester, ether, cyano, nitro, and azido. Each possibility represents a separate embodiment of the present invention. In certain embodiments, the organic molecule is selected from trimethylchlorosilane (TMCS) and methyltrimethoxysilane (MTMS). In a currently preferred embodiment, the organic molecules comprise trimethylchlorosilane (TMCS). Additional information on the modification of the ceramic aerogel substrates can be found in U.S. Pat. No. 5,738,801 and Yokogawa, H. “Hydrophobic Silica Aerogel” Handbook of sol-gel science and technology 3 (2005): 73-84.

In some embodiments, the chemically modified surface portion of the aerogel substrate includes one or more layers of adsorbed organic molecules. In certain such embodiments, the organic molecules are adsorbed on the surface atoms of the aerogel material. In certain embodiments, the chemically modified surface portion includes a monolayer of adsorbed organic molecules.

The methods suitable for chemical modification of the surface portion of the substrate by the adsorption of organic molecules include, but are not limited to, dipping, evaporation, self-assembled monolayers, Langmuir Blodgett, or a combination thereof. In some embodiments, the CPD tank is depressurized at the rate of about 100 psi/min

In some embodiments, the step of providing the aerogel having a nanoporous structure, the substrate comprising a bulk portion and a surface portion, wherein the surface portion is chemically or physically modified, comprises physically modifying the surface portion of the aerogel substrate. In further embodiments, the method of the physical modification of the ceramic aerogel surface portion includes etching. The etching can be performed by a technique selected from dry etching, wet chemical etching or a combination thereof. Each possibility represents a separate embodiment of the invention. According to some embodiments, the etching is performed for at least about 1 minute. According to further embodiments, the etching is performed for at least about 2 minutes. According to yet further embodiments, the etching is performed for at least about 3 minutes.

In some embodiments, the etching is a dry etching. In further embodiments, the dry etching includes ion beam etching. According to some embodiments, the ion beam etching is performed for at least about 1 minute. According to further embodiments, the ion beam etching is performed for at least about 2 minutes. According to yet further embodiments, the ion beam etching is performed for at least about 3 minutes. In further embodiments, the ion bean etching is performed at a pressure of less than about 1×10⁻⁴ Torr. In yet further embodiments, the ion bean etching is performed at the ion bean etching is performed at a beam energy of about 2.5 keV. In further embodiments, the ion bean etching is performed at a current of about 80 μA.

According to some embodiments, the deposition of the metal is initiated within less than about 60 minutes from the termination of the etching process. According to some embodiments, the deposition of the metal is initiated within less than about 50 minutes from the termination of the etching process, less than about 40 minutes, less than about 30 minutes, less than about 20 minutes, or less than about 10 minutes. Each possibility represents a separate embodiment of the invention.

Without wishing to being bound by a theory or mechanism of action, it is contemplated that the etching increases the mean pore size of the surface portion of the ceramic aerogel substrate. According to some embodiments, the etching of the ceramic aerogel substrate provides a surface portion which has a mean pore size ranging from about 2 nm to about 50 nm, from about 5 nm to about 40 nm, from about 10 nm to about 50 nm, from about 10 nm to about 40 nm, from about 20 nm to about 50 nm, from about 30 nm to about 50 nm, or from about 10 nm to about 30 nm. Each possibility represents a separate embodiment of the invention.

Physical Vapor Deposition process

Physical vapor deposition relates to a variety of vacuum deposition methods used to deposit thin films by the condensation of a vaporized form of the desired film material onto various substrate surfaces. Different types of PVD include:

Cathodic Arc Deposition, in which an electric arc is used to vaporize material from a cathode target and the vaporized material then condenses on a substrate, forming a thin film;

Electron beam physical vapor deposition, in which the material to be deposited is heated to a high vapor pressure by electron bombardment in high vacuum and is transported by diffusion to be deposited by condensation on the (cooler) substrate;

Evaporative deposition, in which the material to be deposited is heated to a high vapor pressure by electrically resistive heating in low vacuum;

Pulsed laser deposition, in which a high-power laser ablates material from the target into a vapor; and

Sputter deposition, in which a glow plasma discharge (usually localized around the target by a magnet) bombards the material sputtering some away as a vapor for subsequent deposition.

According to various embodiments of the present invention, the PVD process is selected from sputter deposition or evaporative deposition. Each possibility represents a separate embodiment of the invention.

In certain embodiments, the PVD process is sputter deposition. Sputter deposition involves ejecting material from a target that is a deposition source onto a substrate to be coated. High DC voltages are usually employed in order to induce material ejection from the target. Resputtering is re-emission of the deposited material during the deposition process by ion or atom bombardment. Sputtered atoms ejected from the target have a wide energy distribution, typically up to tens of eV (100,000 K). The sputtered ions (typically only a small fraction of the ejected particles are ionized—on the order of 1%) can ballistically fly from the target in straight lines and impact energetically on the substrates or vacuum chamber (causing resputtering). Alternatively, at higher gas pressures, the ions collide with the gas atoms that act as a moderator and move diffusively, reaching the substrates or vacuum chamber wall and condensing after undergoing a random walk. The entire range from high-energy ballistic impact to low-energy thermalized motion is accessible by changing the background gas pressure. The sputtering gas is often an inert gas such as argon. For efficient momentum transfer, the atomic weight of the sputtering gas should be close to the atomic weight of the target, so for sputtering light elements neon is preferable, while for heavy elements krypton or xenon are used. Reactive gases can also be used to sputter compounds. The compound can be formed on the target surface, in-flight or on the substrate depending on the process parameters.

The non-limiting examples of sputter deposition techniques include magnetron sputtering, plasma sputtering, ion-beam sputtering, reactive sputtering, ion-assisted deposition, high-target-utilization sputtering, and gas flow sputtering. Sputtering sources, including a magnetron sputtering, often employ magnetrons that utilize strong electric and magnetic fields to confine charged plasma particles close to the surface of the sputter target. In magnetic field electrons follow helical paths around magnetic field lines undergoing more ionizing collisions with gaseous neutrals near the target surface than would otherwise occur. Ion-beam sputtering (IBS) is a method in which the target is external to the ion source. In reactive sputtering, the deposited film is formed by chemical reaction between the target material and a gas which is introduced into the vacuum chamber. For example, metal oxide nanoporous films according to the principles of the present invention can be fabricated using reactive sputtering. The composition of the film can be controlled by varying the relative pressures of the inert and reactive gases. In ion-assisted deposition (IAD), the substrate is exposed to a secondary ion beam operating at a lower power than the sputter gun. High-target-utilization sputtering employs remote generation of a high density plasma. The plasma is generated in a side chamber opening into the main process chamber, containing the target and the substrate to be coated. As the plasma is generated remotely, and not from the target itself (as in conventional magnetron sputtering), the ion current to the target is independent of the voltage applied to the target. Gas flow sputtering employs the hollow cathode effect.

In some exemplary embodiments, the sputter deposition technique includes magnetron sputtering, plasma sputtering, ion-beam sputtering, and reactive sputtering. Each possibility represents a separate embodiment of the invention.

In some embodiments of the present invention, the deposition source comprises a plasma source and a target. In some embodiments, said target is a metal target. A metal target can further include a metal alloy target. In other embodiments, the target is a metal oxide target.

The metal, metal alloy or metal oxide target can comprise metals selected from, but not limited to, Au, Ag, Pt, Al, Cu, Ti, Be, Ca, Sr, Ba, Sc, Y, La, Ce, Pr, Nd, Pm, Sm, Eu, Gd, Tb, Dy, Ho, Er, Tm, Yb, Lu, Zr, Hf, Zn, Cd, Ga, In, Se, Te, V, Nb, Ta, Cr, Mo, W, Mn, Tc, Re, Fe, Ru, Os, Co, Rh, Ni, Pd, Tl, Pb, and combinations thereof. In certain embodiments, metal, metal alloy or metal oxide target includes metals selected from Au, Ag, Pt, Al, Cu, Ti, and combinations thereof.

Sputter deposition can be performed by using an industrial type deposition equipment or an on-desk type equipment.

In a typical sputter deposition process for the deposition of metal films, the plasma source operates at a power of about 100-150 W during the deposition step. In contrast, according to some currently preferred embodiments, the plasma source operates at a power of lower than about 90 W during the deposition step. In some embodiments, the plasma source operates at a power of lower than about 80 W during the deposition step, at a power of lower than about 75 W, lower than about 70 W, lower than about 65 W, lower than about 60 W, or lower than about 55 W. Each possibility represents a separate embodiment of the invention. Without wishing to being bound by theory or mechanism of action, it is contemplated that the relatively low power of the plasma source enables the formation of the nanoporous metal-based film on the chemically or physically modified surface portion of the ceramic aerogel substrate.

In some exemplary embodiments, the sputter deposition comprises a preliminary step of the plasma source ignition, during which the aerogel substrate is not exposed to the plasma source.

In some currently preferred embodiments, the plasma source operates at a current ranging from about 0.5 mA to about 100 mA, In some embodiments, the plasma source operates at a current ranging from about 0.5 mA to about 40 mA. In further embodiments, the plasma source operates at a current ranging from about 1 mA to about 30 mA, or from about 10 mA to about 20 mA. Each possibility represents a separate embodiment of the invention.

In some embodiments, the plasma source operates at a beam energy ranging from about 5 keV to about 15 keV. In certain embodiments, the plasma source operates at a beam energy of about 10 keV.

In some embodiments, the sputter deposition continues for up to about 10 minutes. In further embodiments, the sputter deposition continues for up to about 9 minutes. In yet further embodiments, the sputter deposition continues for up to about 8 minutes. In still further embodiments, the sputter deposition continues for up to about 7 minutes. In yet further embodiments, the sputter deposition continues for up to about 6 minutes. In still further embodiments, the sputter deposition continues for up to about 5 minutes. It has been found by the inventors of the present invention that substantially longer deposition times did not provide nanoporous structure of the deposited metal-based films.

In some embodiments, the sputter deposition process is performed with an inert sputtering gas. The inert sputtering gas can be selected from argon (Ar), neon (Ne), krypton (Kr) or xenon (Xe). In some embodiments, the sputter deposition process is performed with a reactive sputtering gas. The reactive gas can be oxygen (O₂).

According to some embodiments, sputter deposition is performed at a working pressure of from about 0.05 mTorr to 100 mTorr. According to certain embodiments, sputter deposition is performed at a working pressure of from about 2.5 mTorr to about 4.5 mTorr. In some embodiments, the sputter deposition is an ion beam sputtering.

In other embodiments, sputter deposition is performed at a working pressure of below about 1 mTorr. In additional embodiments, sputter deposition is performed at a working pressure of from 20 to 100 mTorr. In some embodiments, the sputter deposition is a plasma sputtering.

According to further embodiments, the flow rate of the sputtering gas is from about 1.5 to about 3.5 sccm. In certain embodiments, the flow rate is about 2.5 sccm.

According to some embodiments, the ceramic aerogel substrate is rotated during the film deposition. According to further embodiments, the rotation speed is between about 1 rpm and 10 rpm.

In certain embodiments, the PVD process is evaporative deposition.

Evaporative deposition is a common method of thin-film deposition. The source material is evaporated in a vacuum. The vacuum allows vapor particles to travel directly to the substrate, where they condense back to a solid state.

In some embodiments, the deposition source comprises a metal or a metal oxide source and an energy source that evaporates the metal or metal oxide. In still further embodiments, the energy source operates at a current ranging from about 0.5 mA to about 100 mA. In yet further embodiments, the energy source operates at a current ranging from about 1 mA to about 100 mA. In still further embodiments, the energy source operates at a current ranging from about 5 mA to about 75 mA. In yet further embodiments, the energy source operates at a current ranging from about 10 mA to about 50 mA. In additional embodiments, the energy source operates at a current ranging from about 1 mA to about 10 mA, from about 10 mA to about 20 mA, from about 20 mA to about 30 mA, from about 30 mA to about 40 mA, from about 40 mA to about 50 mA, from about 50 mA to about 60 mA, from about 60 mA to about 70 mA, from about 70 mA to about 80 mA, from about 80 mA to about 90 mA, or from about 90 mA to about 100 mA. Each possibility represents a separate embodiment of the invention

The evaporative deposition according to the principles of the present invention can continue from about 1 minutes to about 20 minutes. In some embodiments, the evaporative deposition continues from about 1 minutes to about 15 minutes. In further embodiments, the evaporative deposition continues from about 1 minutes to about 10 minutes. In yet further embodiments, the evaporative deposition continues from about 1 minutes to about 5 minutes.

According to some embodiments, the ceramic aerogel substrate is rotated during the film deposition. According to further embodiments, the rotation speed is between about 1 rpm and 10 rpm. According to further embodiments, the distance between the metal or a metal oxide source and the ceramic aerogel substrate is from about 30 to about 60 cm.

Nanoporous Metal-Based Film

The invention further provides nanoporous metal-based films, being lightweight, transparent and having ultralow density. In one aspect, there is provided a nanoporous metal-based film supported on a ceramic aerogel substrate having a nanoporous structure and an electrostatic surface, wherein the nanoporous structure and an electrostatic surface of the aerogel define the nanoporous structure of the metal-based film. In another aspect, there is provided a nanoporous metal-based film, prepared according to the method of the present invention. In some embodiments, the metal-based film has a purity of at least about 98% wt, at least about 99% wt, at least about 99.5% wt or at least about 99.8% wt. Each possibility represents a separate embodiment of the invention. In some embodiments, the metal based film of the invention is three dimensional isotropic.

As used herein and in the claims the term “pure” refers to the low content of other ingredients, in the metal-based film of the invention. Accordingly, the amount of other materials in the metal-based film is no more than a predetermined amount specified in % wt, i.e. a film with purity of at least about 98% wt means that the metal-based film comprises at least 98% of the nanopouros metal component of the invention. In some embodiments, the metal based film of the invention is three dimensional isotropic.

The nanoporous metal-based film, prepared according to the method of the present invention can be supported on the ceramic aerogel substrate. In certain such embodiments, the aerogel substrate is configured not only to induce formation of the nanoporous film but also to improve handling of the obtained film. However, if necessary, the aerogel substrate can be relatively easily detached from the nanoporous film. Thus, in some embodiments, the nanoporous metal-based film is not supported on a ceramic aerogel substrate. In certain such embodiments, the method of the invention further comprises a step of separating the metal-based film from the ceramic aerogel substrate. The step of separating the metal-based film from the ceramic aerogel substrate can be performed by an etching technique including dry etching or wet chemical etching, or by cutting or pealing of the film from the aerogel substrate.

The metal-based nanoporous film according to the principles of the present invention, can include a metal film, a metal alloy film, a metal oxide film or a metal nitride film. Each possibility represents a separate embodiment of the invention. The metal, metal alloy, metal oxide or metal nitride film can comprise a metal selected from, but not limited to, Au, Ag, Pt, Al, Cu, Ti, Be, Ca, Sr, Ba, Sc, Y, La, Ce, Pr, Nd, Pm, Sm, Eu, Gd, Tb, Dy, Ho, Er, Tm, Yb, Lu, Zr, Hf, Zn, Cd, Ga, In, Se, Te, V, Nb, Ta, Cr, Mo, W, Mn, Tc, Re, Fe, Ru, Os, Co, Rh, Ni, Pd, Tl, Pb, and combinations thereof. In certain embodiments, the nanoporous metal film includes a metal selected from the group consisting of Au, Ag, Pt, Al, Cu, Ti, Fe and combinations thereof. In additional embodiments, the metal comprises a metal alloy, selected from the group consisting of Au/Ag, Au/Fe, Au/Cu, Au/Ag/Cu, Au/Al, Au/Pt, Au/Ti, Au/Ag/Al, Au/Ag/Cu/Pt, Au/Ag/Cu/Al, Au/Ag/Cu/Ti, Pt/Ag, Pt/Cu, Cu/Al, Cu/Ag, Pt/Fe, Pt/Al, Pt/Ag/Cu, Pt/Au/Cu/Ti, Ag/Fe, Cu/Fe, Ti/Fe and Pt/Au/Al. Each possibility represents a separate embodiment of the invention.

The metal oxide film can be selected from the group consisting of CuO, CuO₂, AgO, AgO₂, TiO₂, Al₂O₃, and combinations thereof. Each possibility represents a separate embodiment of the invention.

The non-limiting example of the metal nitride film includes TiN.

In some exemplary embodiments there is provided a silver (Ag) nanoporous film supported on silica aerogel. In further exemplary embodiments there is provided a gold (Au) nanoporous film supported on silica aerogel. In additional exemplary embodiments there is provided an aluminum (Al) nanoporous film supported on silica aerogel. In further exemplary embodiments there is provided a copper (Cu) nanoporous film supported on silica aerogel.

A person skilled in the art will readily appreciate that the shape and size of the nanoporous metal-based film is determined by the dimensions of the ceramic aerogel substrate and/or the dimensions of the PVD chamber. The nanoporous metallic film can have a length, width or a combination thereof of up to about 30 cm or higher. In some exemplary embodiments, the nanoporous metallic film has a length and/or width of about 10 cm.

In some embodiments, the nanoporous metal-based film has a thickness ranging from about 1 nm to about 500 μm. In further embodiments, the nanoporous metal-based film has a thickness ranging from about 10 nm to about 100 μm. In yet further embodiments, the nanoporous metal-based film has a thickness ranging from about 50 nm to about 50 μm. In still further embodiments, the nanoporous metal-based film has a thickness ranging from about 100 nm to about 10 rm. In yet further embodiments, the nanoporous metal-based film has a thickness ranging from about 500 nm to about 1 μm.

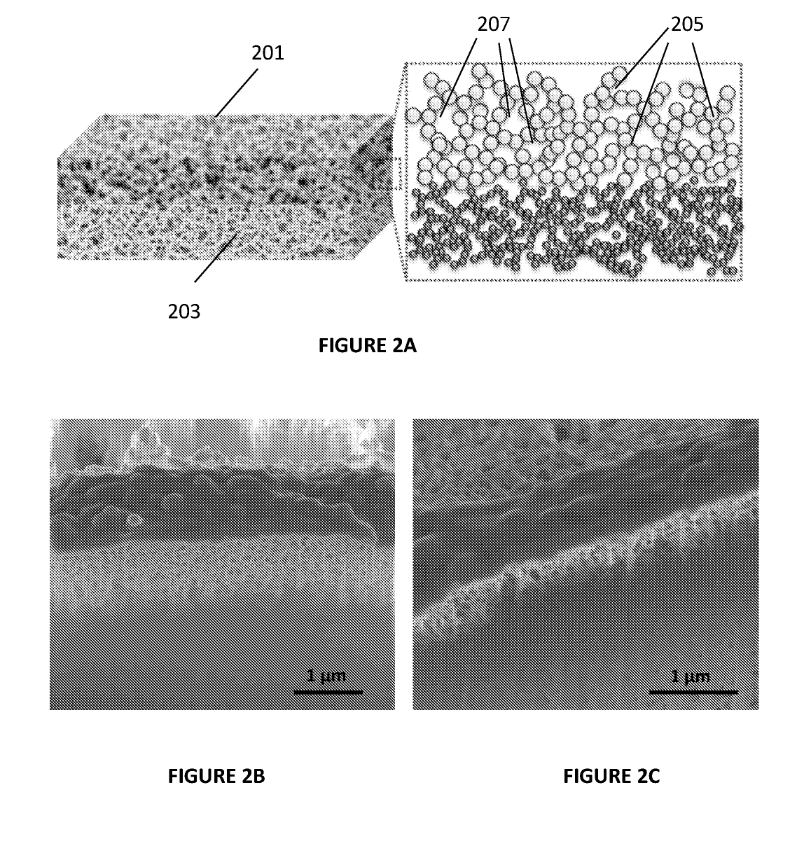

According to some embodiments, the metal-based nanoporous film has a nanoporous structure comprising metal-based interconnected ligaments and percolating nano-pores. FIG. 2A schematically illustrates the nanostructure of metal-based nanoporous film 201 supported on ceramic aerogel substrate 203, the nanoporous film including a plurality of ligaments 205 and plurality of nano-pores 207, according to some embodiments of the invention. The term “ligament”, as used herein, refers to a structure having one dimension (referred to as the length of the structure) elongated with respect to the other two dimensions (referred to as the thickness and the width of the structure). The ligament can have a circle-like cross section, or equivalent dimensions wherein the ligament has other cross sectional shapes including, but not limited to, trapezoidal, triangular, square, strips or rectangular.

FIGS. 2B and 2C represent the HR-SEM images of the cross sectional view of the gold (FIG. 2B) and silver (FIG. 2C) nanoporous film (seen as a brighter layer in the middle of the image) supported on the silica aerogel substrate (seen as a darker layer in the bottom side of the image). Nanopores of the Au and Ag films can be clearly seen in FIGS. 2A and 2B and nanopores of the silica aerogel can be seen in FIG. 2C.

The nanoporous structure of the metal-based film can be defined by at least one property selected from a mean pore size, pore distribution, and interconnected ligaments thickness.

In some embodiments, the nanoporous metal-based film has a mean pore size ranging from about 10 nm to about 500 nm. In further embodiments, the nanoporous metal-based film has a mean pore size ranging from about 20 nm to about 400 nm. In yet further embodiments, the nanoporous metal-based film has a mean pore size ranging from about 30 nm to about 300 nm. In still further embodiments, the nanoporous metal0-based film has a mean pore size ranging from about 40 nm to about 200 nm. In a currently preferred embodiment, the nanoporous metal-based film has a mean pore size ranging from about 50 nm to about 500 nm.

In certain embodiments, the nanoporous metal-based film has a substantially uniform pore distribution. The term “uniform pore distribution”, as used herein, refers to a variation of the pore volume between two different portions of the metal-based film of less than about 20%. In further embodiments, the term refers to a variation of less than about 15%, less than about 10% or less than about 5%. Each possibility represents a separate embodiment of the invention.

In some embodiments, the metal-based interconnected ligaments have a mean thickness ranging from about 5 nm to about 300 nm. In further embodiments, the metal-based interconnected ligaments have a mean thickness ranging from about 5 nm to about 200 nm. In yet further embodiments, the metal-based interconnected ligaments have a mean thickness ranging from about 10 nm to about 100 nm. In some embodiments, the metal-based interconnected ligaments have a mean width ranging from about 5 nm to about 300 nm. In further embodiments, the metal-based interconnected ligaments have a mean width ranging from about 5 nm to about 200 nm. In still further embodiments, the metal-based interconnected ligaments have a mean width ranging from about 10 nm to about 100 nm. In some embodiments, the terms “thickness” and “width” can be used interchangeably. In some related embodiments, the ligament has a circle-like cross section, thus, the ligament thickness can be referred to as ligament diameter. In other related embodiments, the metal-based interconnected ligaments have strings-of-pearls-like morphology, which comprises well connected nanoparticles. In some embodiments, the ligament hold a bouncy texture (i.e. not smooth), comprising multiple tip-shaped nanoparticles. In some other embodiments, the ligaments are uniform in thickness and the pores are bimodal in size, ranging from a few tens to a few hundred nm. As used herein and in the claims, the term “bimodal” refers to a bimodal distribution, describing a continuous distribution over a range of pore sizes characterized in two main modes dominating the pore size range. Without being bound by any theory or mechanism, it is contemplated that this network is more flexible than the substrate network.

In some embodiments, the present invention provides a flexible free-standing nanoporous metal-based film which is not attached to the silica aerogel support it was originally formed on as a substrate. In some related embodiments, the nanoporous metal-based film of the invention, can be further used to produce such flexible free-standing nanoporous metal-based film by the removal of the silica aerogel substrate away from the metal networks. In some embodiments the present invention provides a method for the preparation of a flexible free-standing nanoporous metal-based film comprising the steps of (a) providing a nanoporous metal-based film of the invention and (b) separating the silica aerogel substrate from the metal-based film. The Separation of the silica aerogel substrate can be performed by a method selected from peeling, dry etching, wet chemical etching, cutting or any combination thereof. In a specific embodiment, the peeling in step (b) is carried utilizing an adhesive material attached to the silica aerogel substrate surface. The peeling can be achieved by pulling the adhesive material away from the metal-based film, thereby leaving the metal-based film without the silica aerogel support. In some embodiments, the present invention provides a flexible free-standing nanoporous metal-based film, comprising three dimensional metallic networks having a thickness of from about 200 nm to about 10 m, a pore size of about 50 to 500 nm, and wherein said film is transparent to visible, near IR and ultra-violet (UV) spectra region. In an additional embodiment, said flexible free-standing nanoporous metal-based film is for use in energy storage systems, energy supply systems, hydrogen storage systems, sensors, optics, optoelectronics, catalysis or any combination thereof. As used herein and in the claims the term “flexible free-standing” refers to a nanoporous metal-based film which was separated from the silica aerogel support on which it was originally formed. Said film maintains its metallic three dimensional networks structure and can regain its shape after mechanical folding, for example, between two tweezers. Without being bound by any theory or mechanism of action, it is contemplated that the ability to delaminate or remove the silica substrate from the metallic network is of outstanding importance since it allows protecting the metallic surface, having an enlarged surface area, from the surroundings. The network is kept protected until such surface is required for use in catalytic activity.

According to some embodiments, the nanoporous structure of the ceramic aerogel substrate defines the mean pore size of the metal-based nanoporous film. According to further embodiments, the nanoporous structure of the ceramic aerogel substrate defines the pore distribution of the metal-based nanoporous film. According to additional embodiments, the nanoporous structure of the ceramic aerogel substrate defines the mean thickness of the metal-based interconnected ligaments.

According to some embodiments, the nanoporous metal-based film of the present invention is transparent in the visible, near-IR and ultra-violet spectra region. The term “transparent” as used herein refers to a material which transmits an average of greater than about 50% of incident electromagnetic radiation across the visible, near-IR and ultra-violet spectra. In further embodiments, “transparent” means that a material transmits greater than about 60%, 70%, or 80% of incident electromagnetic radiation across the visible, near-IR and ultra-violet spectra. Each possibility represents a separate embodiment of the invention.

According to some embodiments, the nanoporous structure of the ceramic aerogel substrate defines the optical properties and/or the electronic properties of the metal-based film. For example, mean pore size of the aerogel substrate can be tuned in order to alter the transmission of nanoporous film or conductivity thereof. Without wishing to being bound by a theory or mechanism of action, it is contemplated that the alteration of the silica aerogel leads to an alteration in the metal nanostructure. The alteration in the metal nanostructure provides tunability in the optical and electrical properties thereof.

Nanoporous metal and metal oxide materials can be extensively used in different technological fields. According to some embodiments, the nanoporous metal-based films of the present invention are characterized by high surface area, low density, conductivity, transparency and catalytic activity. Said properties can find utility in a vast number of applications. Additionally, the combination of metallic properties with nanoporosity not only dramatically reduces the metal density but also allows permeability of materials, including gases, liquids and solids. The nanoporous metal-based film can be used in various applications, such as, but not limited to energy storage systems, energy supply systems, hydrogen storage systems, sensors, optics, optoelectronics, catalysis or any combination thereof.

In some embodiments, the nanoporous metal-based film is configured for use as a catalyst, for example in hydrogen storage or fuel cells applications. Without wishing to being bound by theory or mechanism of action, the relatively high surface are of the nanoporous metal-based film can enhance any catalytic activity and improve the reaction kinetics. The nanoporous metal-based film according to the principles of the present invention can be used for catalyzing reactions of alcohol or hydrocarbon oxidation and oxygen reduction.

In some embodiments, the nanoporous metal-based film is configured for use in the production of solar fuel. In some other embodiments, the nanoporous metal-based film is configured for use in CO₂ catalysis. In some embodiments, the nanoporous metal-based film is configured for use in solar cells or optoelectronic devices. Without wishing to being bound by theory or mechanism of action, the transparency, conductivity and nanostructure of the film provide unique transport properties.

In some embodiments, the nanoporous metal-based film is configured for use in optical devices and metamaterials. Without wishing to being bound by theory or mechanism of action, the nanoporous metal-based film provides a significant electro-field enhancement.

In some embodiments, the nanoporous metal-based film is configured for use in optical sensing, for example in chemical or biological sensors based on surface enhanced Raman spectroscopy (SERS) enhanced signals or other plasmonic-based sensors.

In some embodiments, the nanoporous metal-based film is configured for use in batteries or supercapacitors, for example, as a high-surface porous electrode. Without wishing to being bound by theory or mechanism of action, the open porous structure of the metal-based nanoporous film provides ideal channels for ion transport into and out of the electrodes and thus affords for faster charging and discharging electrode reactions, without volume change of the electrode.

As used herein and in the appended claims the singular forms “a”, “an,” and “the” include plural references unless the content clearly dictates otherwise. Thus, for example, reference to “a surface portion” includes a plurality of such surface portions and equivalents thereof known to those skilled in the art, and so forth. It should be noted that the term “and” or the term “or” is generally employed in its sense including “and/or” unless the content clearly dictates otherwise.

As used herein, the term “about”, when referring to a measurable value such as an amount, a temporal duration, and the like, is meant to encompass variations of +/−10%, more preferably +/−5%, even more preferably +/−1%, and still more preferably +/−0.1% from the specified value, as such variations are appropriate to perform the disclosed methods.

The following examples are presented in order to more fully illustrate some embodiments of the invention. They should, in no way be construed, however, as limiting the broad scope of the invention. One skilled in the art can readily devise many variations and modifications of the principles disclosed herein without departing from the scope of the invention.

### EXAMPLES

Characterization Methods

Optical imaging and spectral measurements of the nanoporous metallic films were done using an inverted light microscope in transmission mode (IX83, Olympus). The specimens were illuminated with a collimated light, which is generated by a xenon light source (175 W, Lambda). Spectroscopic data acquisition is done by a spectrograph (IsoPlane SCT320, Princeton Instruments) using the LightField program. The spectrograph provides both spectral and spatial information. The measurements are done in the spectral range of 400 to 700 nm for which the sensitivity of the system is optimal.

### Example 1—Modified Preparation Procedure of the Aerogel Substrate

Three main steps are involved in the custom synthesis of silica aerogel substrates. First, silica alcogels are fabricated by a sol-gel technique in a one-step procedure. Then, the alcohol within the gel matrix is exchanged with highly pure (99.99%) liquid carbon dioxide (CO₂). Finally, CO₂ is brought into a supercritical condition and slowly removed out of the gel pores leaving a dry solid lightweight body (silica aerogel). Hereinbelow, the preparation method is described including the specific modification of the commonly used procedure.

The sol-gel process included hydrolysis and polycondensation of tetraethyl orthosilicate (TEOS, 98% purity, Sigma Aldrich) in the presence of a catalyst. Since the intended thickness of the aerogel substrate was about 1 mm, the reaction mixture was kept at room temperature. The preparation procedure intentionally avoided the sequential aging step of the alcogels in order to provide the desired substrate surface modification. The custom aging procedure includes a week-long suspension of the alcogels while daily renewing the solvent in the bath.

Special designated molds were prepared in the workshop using aluminum stubs. A circular well (8 mm diameter, 1 mm thickness) was machined in each stub to allow performance of all the synthesis stages in the same mold. A volume of 100 μL sol was poured into each mold. It is of great importance to seal the molds under a supersaturated alcoholic vapor atmosphere during the gelation time. After exactly 15 min, the alcogels were placed under pure extra-dry ethanol to prevent evaporative drying for 12 hours.

For the supercritical drying step, a designated devices for mounting the molds in the critical point dryer (CPD) was produced in the workshop, comprising of a protective cover to reduce the substrate damage during the delicate supercritical drying process. The supercritical drying was performed in a CPD. The CPD tank was cooled to 5° C. and then the alcogel substrates were placed in an empty tank. It is unlike the common procedure in which the substrates are placed into previously filled ethanol tank. However, although the tank was empty of ethanol, it is of high importance to ensure presence of a thin liquid ethanol layer on top of each specimen. Afterwards, liquid CO₂ was introduced into the tank. The gels were suspended inside the tank under a gentle stirring for 3 min and for additional 3 min without stirring. Then, liquid CO₂ was exchanged with a fresh one. The described cycle was repeated for 7 times. Once an indication for a total removal of the ethanol from the specimens was achieved, the chamber was filled with liquid CO₂ and was gradually heated to reach its super critical phase. The chamber was kept under these conditions for 15 min. Afterwards, the supercritical CO₂ was vented very slowly until ambient pressure was reached.

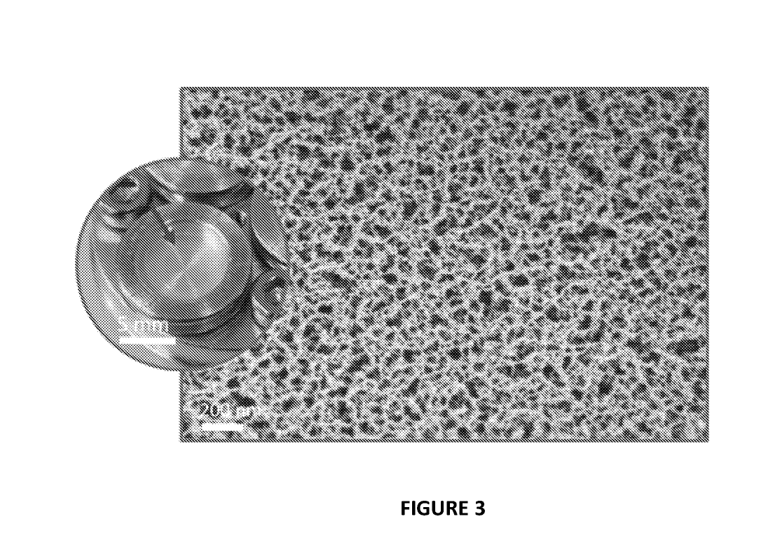

FIG. 3 shows a high resolution scanning electron microscope (HR-SEM) image of SiO₂-aerogel prepared according to the described method. The three-dimensional geometry of the silica comprising interconnected solid nanoparticles with nanoscale pores is clearly observed. The inset shows a photograph of a thin transparent silica aerogel substrate inside aluminum holder after supercritical drying.

### Example 2—Surface Modification of the Aerogel Substrate

Silica aerogels substrates were prepared according to the Silica Aerogel (TEOS, Base-Catalyzed) procedure described at www.aerogels.com. In brief, NH₄F was added to water. Catalyst solution was prepared by mixing NH₄F, water, ammonium hydroxide and ethanol. Alkoxide solution was prepared by mixing TEOS and ethanol. The catalyst solution was poured into the alkoxide solution and stir to obtain a sol. The sol was poured into molds and allowed to gel for approximately 8-15 min. Once the gel has set, it was placed under ethanol and aged for 24 h. The solution was changed to ethanol or acetone 7 times over a course of a week. The alcogel was supercritically dried and depressurize at a rate of ˜7 bar/h.

The obtained aerogel was etched by an ion beam etching technique on a Gatan sputtering machine. The procedure parameters are presented in table 1.

TABLE 1
Ion beam etching parameters

| Chamber pressure | <1 × 10⁻⁴ | Torr |
|---|---|---|
| Beam energy | 2.5 | keV |
| time | 3 | min |
| Gas | Ar | |
| Current | 81 | μA |

### Example 3—Sputter Deposition of a Nanoporous Metal Film

Three different sputtering machines were examined: one of an industrial type (BESTEC) and two on-desk type (Gatan or Desk IV, Denton Vacuum). Sputtering parameters typically employed when using said machines for sputtering of the nanoporous films according to the principles of the present invention are described in Tables 2-4.

TABLE 2
BESTEC sputtering parameters

| Stage rotation | 5 | rpm |
|---|---|---|
| current | — | |
| target distance from stage | 8 | cm |
| Gas flow | 2.7 | sccm |
| Working pressure | 5 × 10⁻⁶ | bar |
| Preliminary pressure | 5 × 10⁻¹ | bar |

TABLE 3
DENTON sputtering parameters

| | | |
|---|---|---|
| Stage rotation | 5-10 | rpm |
| current | 10-20 | mA |
| pressure | 100-50 | mTorr |

TABLE 4
GATAN sputtering parameters

| Chamber pressure | <1 × 10⁻⁴ | Torr |
|---|---|---|
| Beam energy | 10 | keV |
| time | 3 | min |
| Gas | Ar | |
| Current | 614 | μA |

Sputter deposition with an industrial type machine: Unlike the commonly used conditions in which high dc power voltages (100 W or higher) are employed, for sputtering of different metallic materials lower powers were used, which has a crucial importance for the production of the nanoporous metals. Accordingly, an initial high-power voltage was used only for the ignition of the plasma in the sputtering chamber during which the aerogel substrate fabricated by the processes described in Examples 1 and 2, was covered by a shutter. Immediately after ignition the power was reduced to 50 W or less for the deposition process. Using the BESTEC machine, a nanoporous Ag film was produced using an Ag target (Kurt J. Lesker, 99.99% Purity) under deposition parameters including ˜1.5×10-7 Torr preliminary base vacuum pressure, 2.5 sccm Ar flow, ˜3.7×10-3 Torr deposition pressure, 5 min (or less) coating time, 5 rpm substrate rotation, ambient temperature.

### Example 4—Evaporative Deposition of a Nanoporous Metal Film

Evaporative deposition was performed on a BES-TEC machine for 2 min Evaporation process parameters are presented in Table 5.

TABLE 5
Evaporative deposition parameters

| | | |
|---|---|---|
| Stage rotation | 5 | rpm |
| current | 1-100 | mA |
| Pellets distance from stage | 45 | cm |

### Example 5—Structural Properties of the Nanoporous Metal Films

Nanoporous films prepared according to the methods described in Examples 1-4 were characterized by visual inspection, SEM, EDS, GIXRD, Rutherford backscattering spectrometry (RBS), Atomic Force Microscopy (AFM), kelvin probe (contact potential difference), Second-harmonic generation SHG, and Raman.

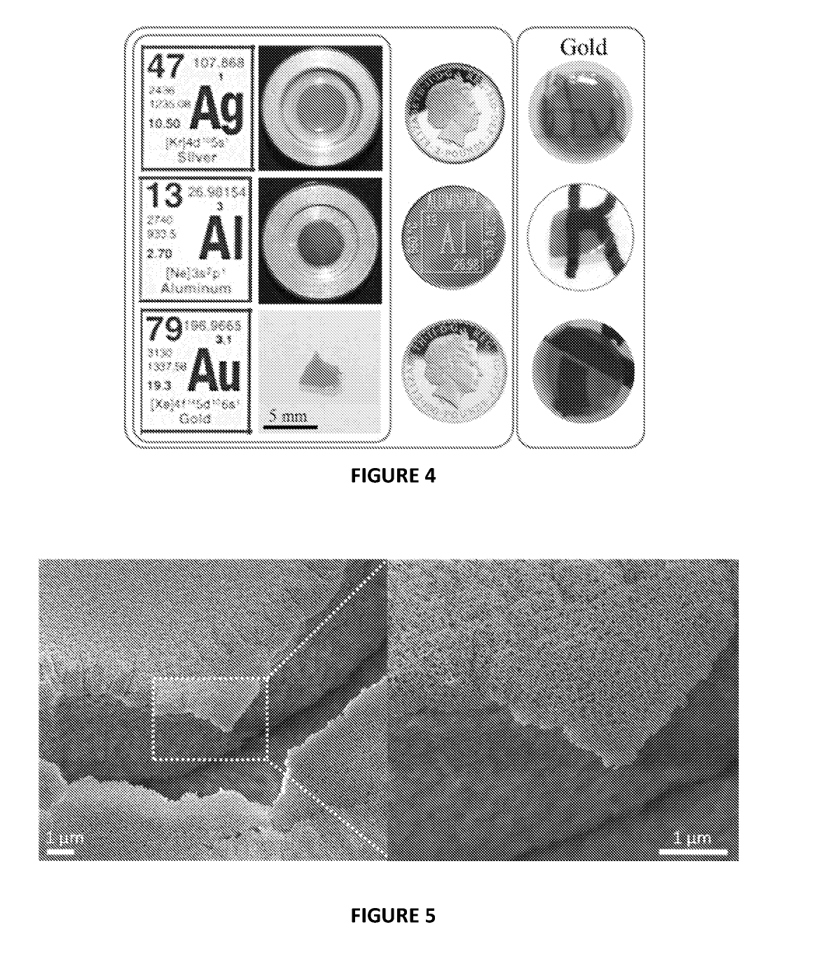

FIG. 4 shows photographs of silver, aluminum and gold nanoporous films prepared according to the procedure described in Examples 1 and 3 (2nd column). The color of the nanoporous films is different from the common bulk color (3rd column). The silver film (upper photograph in the 2nd column) has a gold-like color, the aluminum film (middle) has a brownish color and the gold film has a copper-like color. 4th column shows fabricated gold transparent films which exhibit different colors. It is therefore contemplated that the color of the metallic films and thus their opto-electronic properties can be tuned through the specific nanostructure thereof. It should be emphasized that the ease of the synthesis allows fabrication of large scale superlight metal films.

FIG. 5 shows the high resolution scanning electron microscope (HR-SEM) image of highly porous transparent gold film on top of a silica aerogel substrate prepared according to the procedure described in Examples 1 and 3. The nanoporous metallic film's network is distinctively grown on top of the aerogel substrate, rather than within the aerogel's pores (as can be seen in the inset). The film has an individual structure and be up to a few micrometers in thickness. Due to the film porosity which lies at the nanoscale, the surface area of the Au electrode is extremely high and its density is ultra-low.

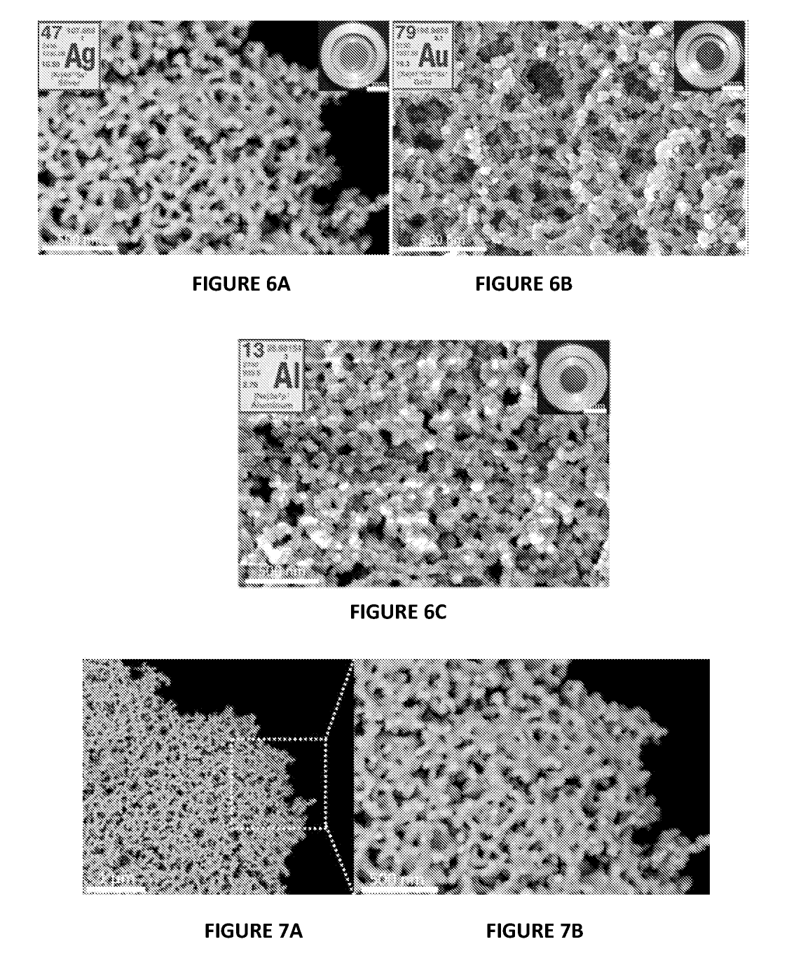

FIGS. 6A-6C show the high resolution scanning electron microscope (HR-SEM) images of nanoporous metallic films which are made of silver (FIG. 6A), gold (FIG. 6B) and aluminum (FIG. 6C), wherein the films were prepared according to the procedure described in Examples 1 and 3. The network chains have a thickness (diameter) of about 50 nm, giving rise to their unique opto-electronic properties and pave the way for efficient catalytic activity. Their ultra-large surface area is demonstrated as well. The insets show photographs of the nanoporous films held in aluminum sample holders. The change in the optical properties of these electrodes can be clearly observed.

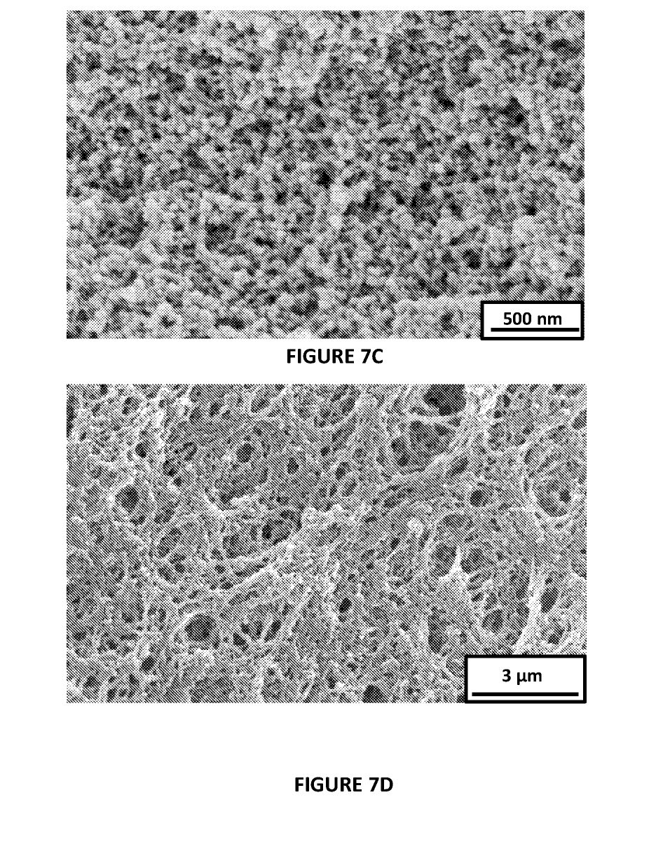

FIGS. 7A-7D show SEM and HRSEM images of the three-dimensional network structure of metal films prepared according to the procedure described in Examples 1 and 3. FIGS. 7A and 7B show SEM images of the nanoporous structure of s silver film, FIG. 7C shows a SEM image of the nanoporous structure of a platinum film and FIG. 7D shows a HR-SEM image of the nanoporous structure of a copper film. It can be therefore concluded that the method of the present invention allows formation on nanoporous films of various metals.

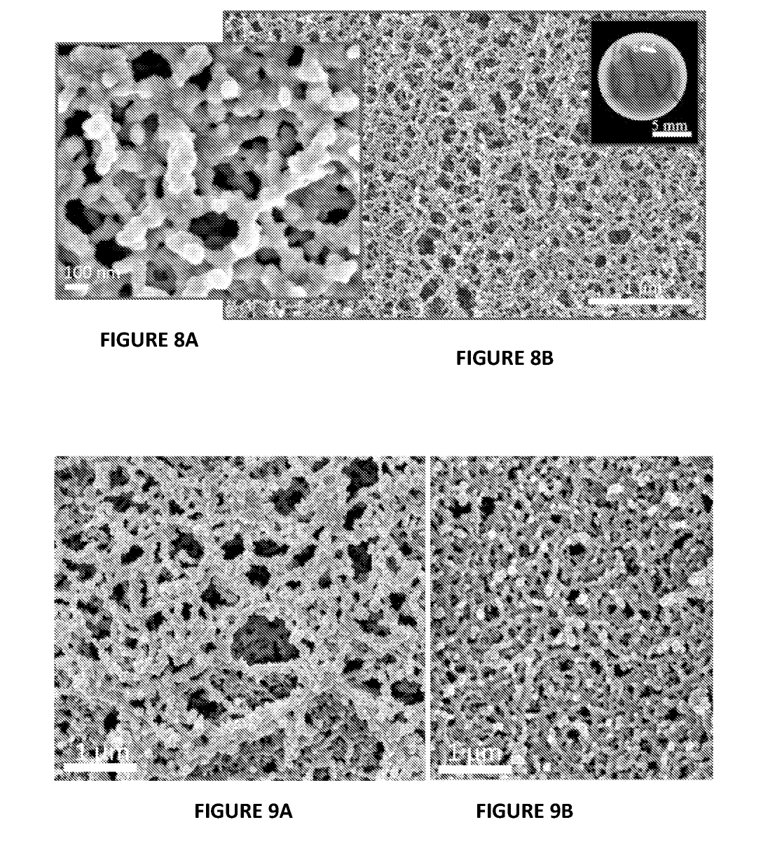

FIGS. 8A and 8B show high- (FIG. 8A) and low- (FIG. 8B) magnification SEM images of an Au film prepared according to the procedure described in Examples 1 and 3 (the photograph in the inset of FIG. 8B). The three-dimensional network structure of the film is verified along the large-scale size of the electrode (here, ˜1 cm in diameter).

FIGS. 9A and 9B show the SEM images of two silver films in which the nanostructure of each networks is prominently different showing the possibility to design and tune the opto-electronic properties of the fabricated films. Without wishing to being bound by theory or mechanism of action, the difference in the nanostructure of said two silver nanoporous films lies in the different amount of the solvent during the preparation of the ceramic aerogel having a chemically modified surface portion.

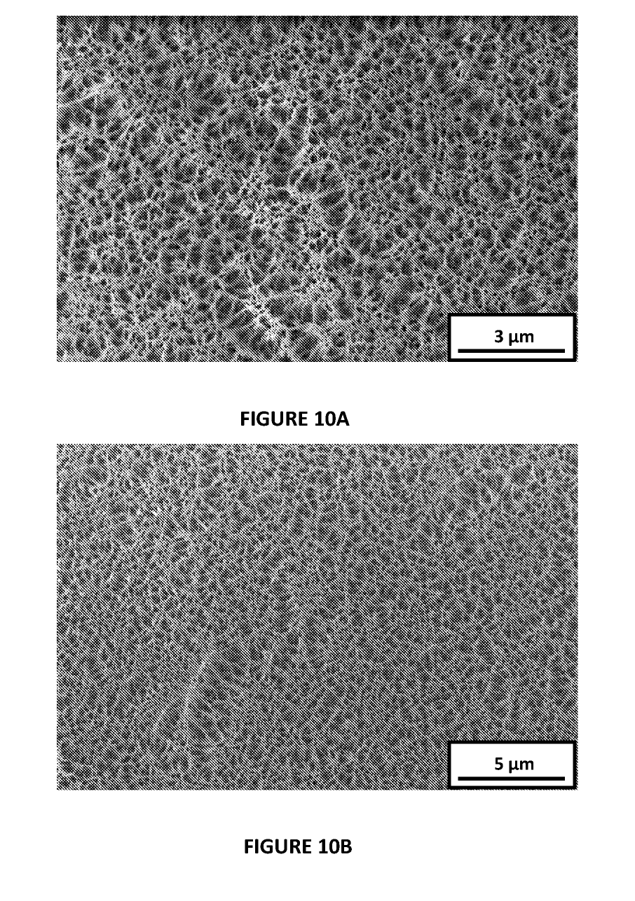

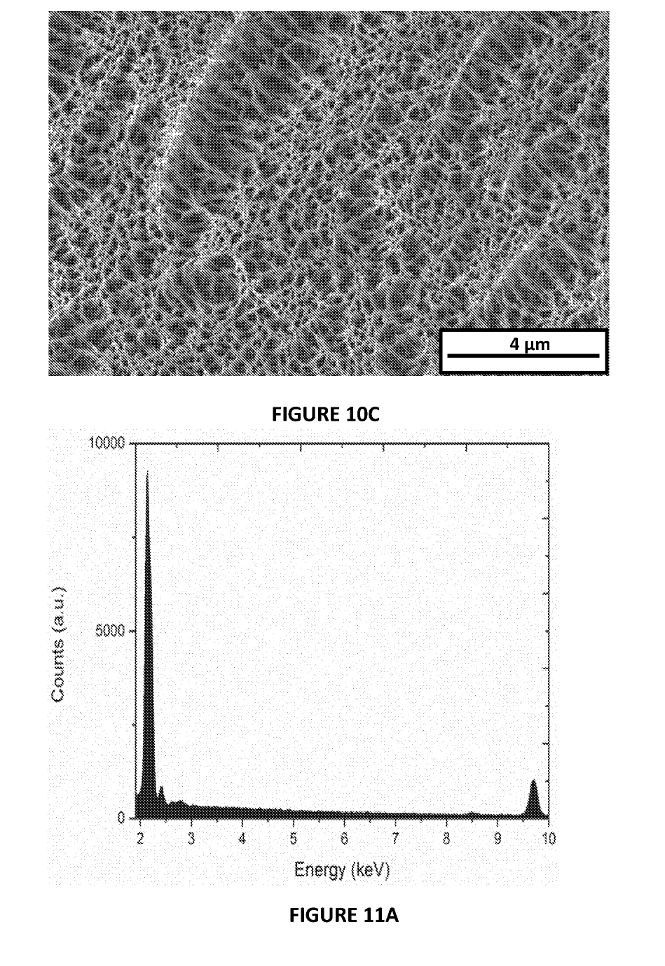

FIGS. 10A-10C show HR-SEM images of the Ag nanoporous films prepared according to the procedure described in Examples 2 and 3, including surface etching of the aerogel substrate. It can be seen that the films possess the desired nanoporous structure containing metallic interconnected ligaments and percolating nano-pores.

### Example 6—Composition of the Nanoporous Metal Films

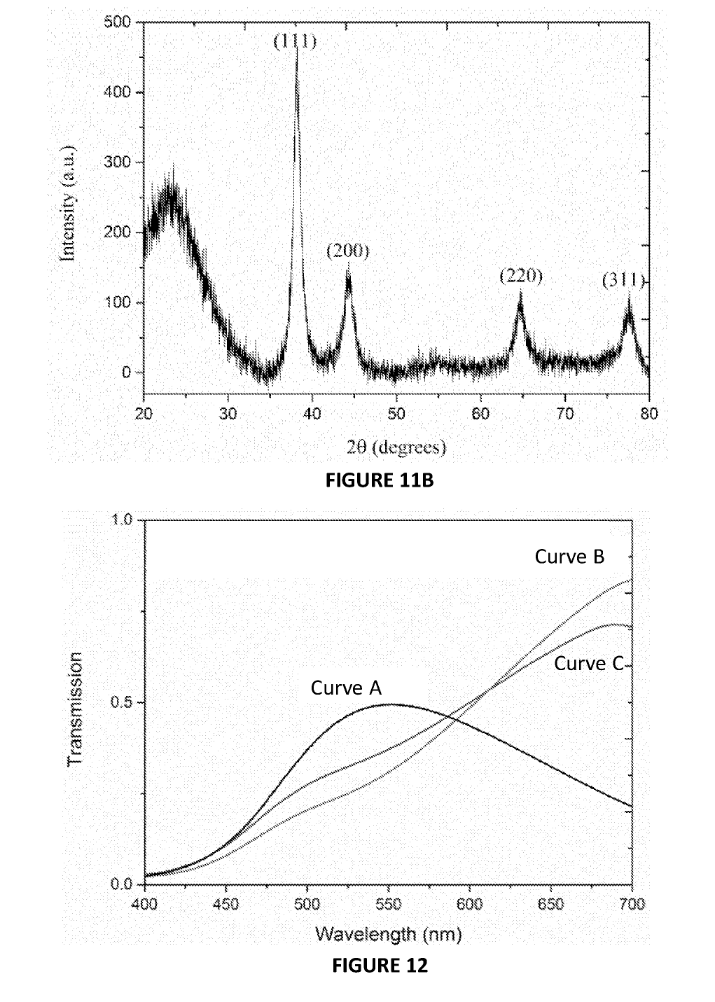

FIGS. 11A and 11B show elemental analysis of the nanoporous Au films prepared by the methods described in Examples 1 and 3 hereinabove. Energy dispersive X-ray spectroscopy (EDS) (FIG. 11A) and grazing-incident X-ray diffraction (GIXRD) (FIG. 11B) measurements confirmed that a metallic gold film is entirely made of Au.

### Example 7—Optical Properties of the Nanoporous Metal Films

FIG. 12 shows optical transmission spectra of a control transparent Au thin-film (curve A) and two different transparent Au nanoporous films prepared by the methods described in Examples 1 and 3 hereinabove (curves B and C). The Au thin-film is a control specimen: it was simultaneously prepared with the two other electrodes. Commercially available glass slides were cleaned using (bath) sonication in ethanol (5 min). Then they were rinsed with ultra-pure H₂O and were dried under an N₂ stream. Then, a metal was deposited by sputtering on the cleaned glass slides (situated at the same location of the aerogel substrates in cases of consequent depositions).

A pronounced red-shift is observed for Au nanoporous network compared to Au film. It should be noted that the transparency of the fabricated Au film which is prepared using an aerogel with larger mean pore size (curve B) is higher than that of the Au film prepared on an aerogel having smaller mean pore size (curve C). Nevertheless, both B and C curves show a very high transparency at the near IR, indicating their potential uses as IR detectors.

### Example 8—Stability of the Nanoporous Metal Films

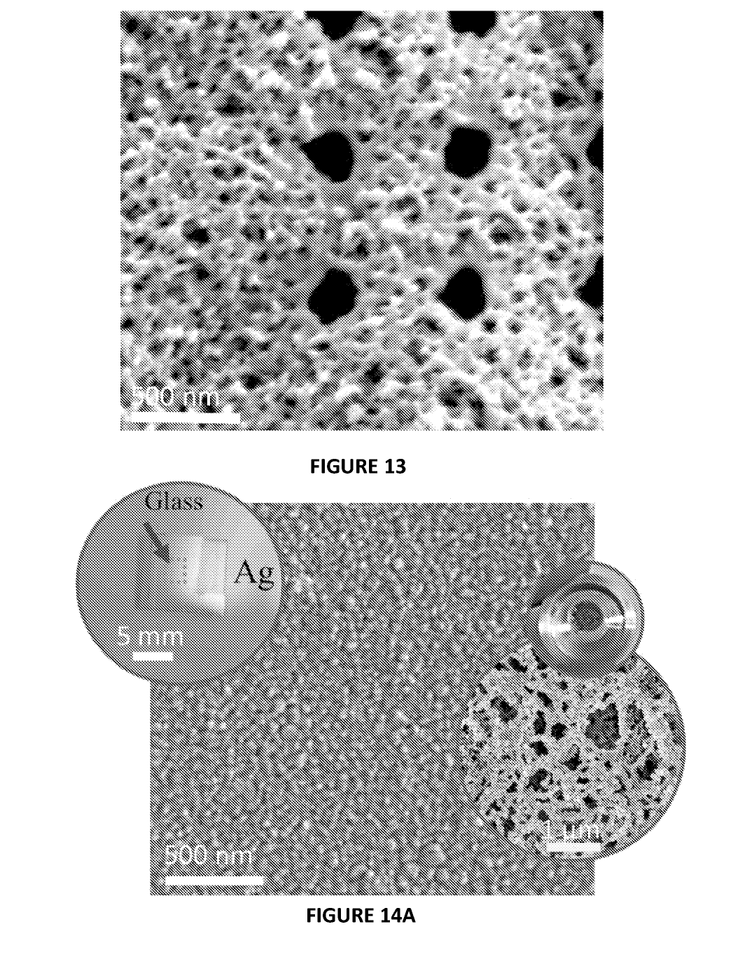

FIG. 13 shows a SEM image of the metallic nanoporous networks of the film modified by focused ion-beam (FIB) milling. Cubic (or hexagonal) sub-wavelength hole arrays were milled in the metal (Ag or Au) films by focused ion-beam (FIB, Helios 600, FEI) microscope. Hole diameter was kept constant at 200 nm and the array period (P) was varied at 400, 420, 440, 460, 480, 500, 540, 580 and 600 nm. Hole shapes were either circular or triangular.

Feasibility of the FIB milling of the nanoporous films is an evidence for the stability of the films' nanostructure. Furthermore, it significantly broadens the number of practically applications of the nanoporous films of the present invention.

### Example 9—Properties of the Metal Films Produced by a Different Process (Comparative Example)

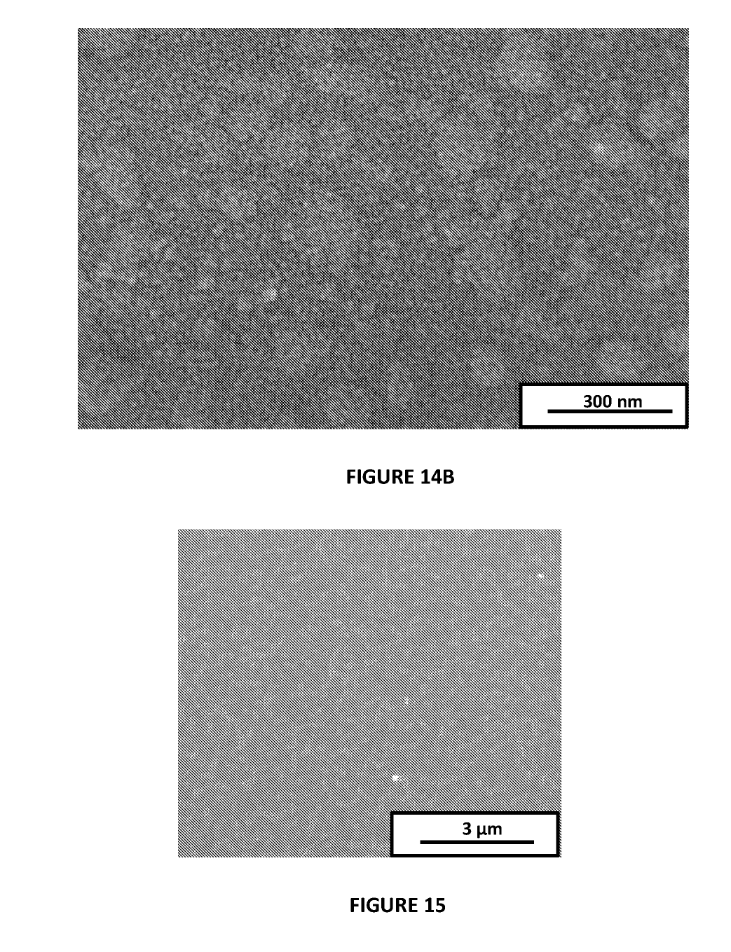

Deposition of metal films on ceramic substrate other than aerogels was studied in order to show the importance of use of an aerogel substrate. FIG. 14A shows the SEM image of an Ag thin-film which was deposited on a glass substrate (left inset). The film comprises fine metallic grains which are uniform and densely-packed all over the substrate. For comparison, a SEM image of a nanoporous silver film deposited on the silica aerogel according to the method of the present invention is shown in the bottom-right inset, in which its three-dimensional porous network is clearly exhibited. The top-right inset shows a photograph of the silver nanoporous film showing its transparency and gold-like color. FIG. 14B shows the HR-SEM image of a Cu thin-film which was deposited on a glass substrate.

Furthermore, additional metal films were prepared by changing the parameters of the preparation procedures described in Examples 1-4.

FIG. 15 shows a SEM image of the Ag film deposited on a silica aerogel, which was not carefully stored against humidity sorption following the supercritical drying process. After a few months it absorbed humidity and as a result significantly shrunk. Therefore it contained smaller pores (pore size in the range of about 2-20 nm), which did not induce the nanoporous structure in the metal.

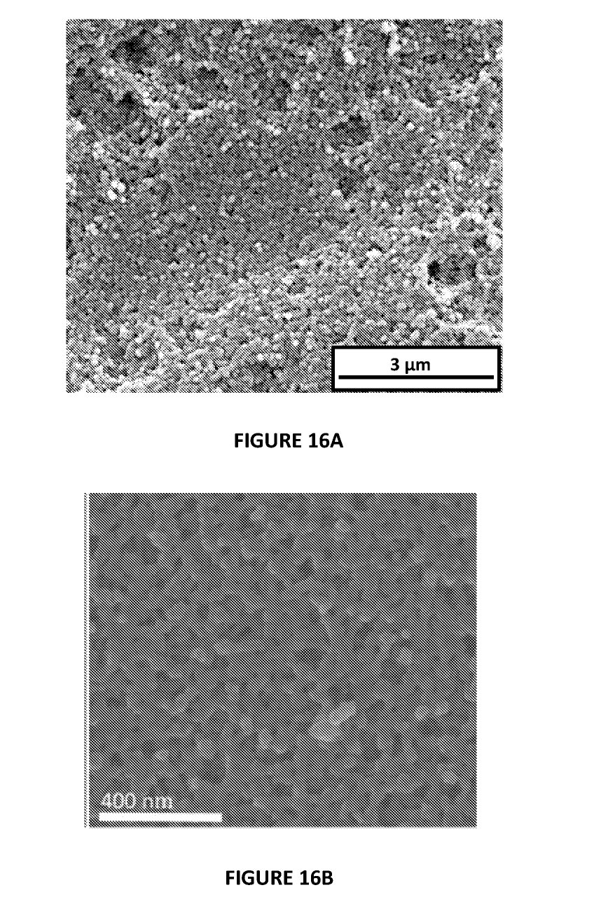

FIG. 16A shows a SEM image of the Ag film deposited on a silica aerogel using high power sputtering conditions (100 W). It can be seen that the obtained film has a completely different nanostructure than the nanoporous films of the present invention. The Ag film obtained in this experiment is not porous but has a relatively dense particulate-like nature. In addition, elongated deposition times (15 min instead of 5 min) yielded a much denser metal film, which is hardly porous (FIG. 16B).

It can be understood that the specific preparation or surface modification of the ceramic aerogel substrates and the film deposition conditions are extremely important for the formation of the desired nanoporous structures.

### Example 10—Controlled Metal Film Formation

The control over the formation of the deposited metal film and the three dimensional metal networks comprising the film can be achieved by controlling the kinetic energy of the condensed metallic atoms. Thinner ligaments composed out of nanoparticles were formed under low beam energy. Gold films were prepared utilizing a modified spattering parameter. The ion-beam energy was tuned as follows:

A) 10 keV; and

B) 4 keV.

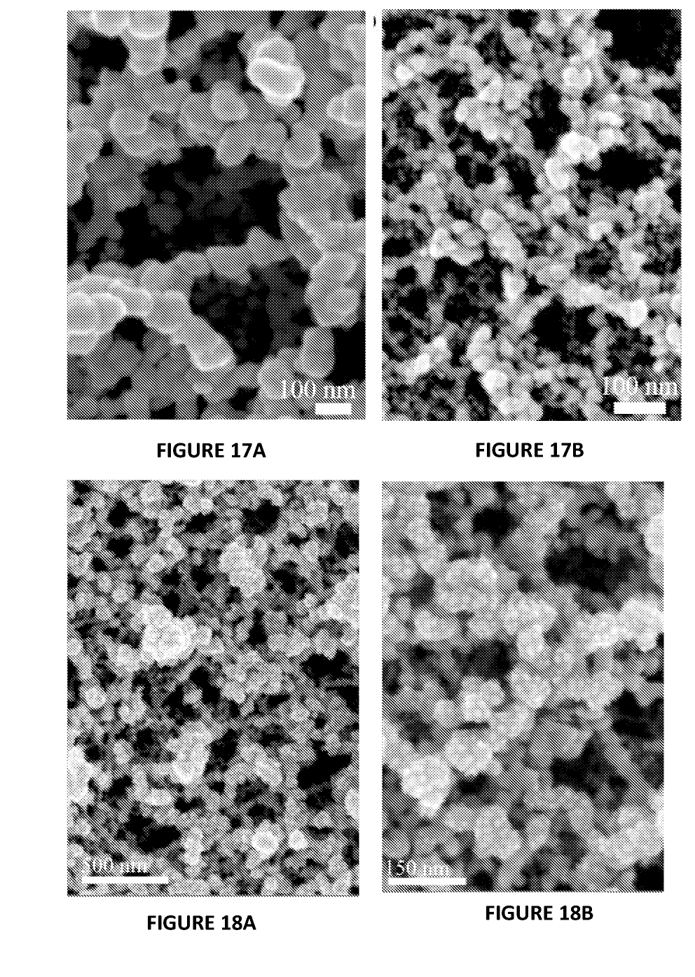

In the case of A, the resulted three dimensional networks had an average ligament size of ˜100 nm (FIG. 17A), while the three dimensional networks formed in B had an average ligament size of ˜30 nm (FIG. 17B). These results demonstrate that the tuning of the ion bean energy can provide a unique level of control utilizing the kinetic energy of the inert gas ions upon colliding.

### Example 11—Characterization of Network Texture

HR-SEM was used in order to further characterize the texture of gold metal networks.

The ligaments forming the three dimensional nanoporous networks hold a unique texture as the ligaments appeared to be covered by high densely packed small (<5 nm) metallic tips, giving them a gritty texture (FIGS. 18A and 18B).

### Example 12—Thickness Analysis of the Nanoporous Metallic Film

Gold and silver-based films were simultaneously grown by sputtering utilizing the conditions as described hereinabove in Example 3 and Table 4, where the sputtering time for silver was 90 seconds and for gold 180 seconds. Both silver and gold were simultaneously sputtered on top of a silica aerogel substrate and on top of a glass slide. Pt was deposited on all specimens for imaging purposes, utilizing CVD. The Pt deposition is carried in the focused ion beam (FIB) chamber. Cross-sectional cuts were carried utilizing FIB milling. The resulted cross-sections were imaged in SEM.

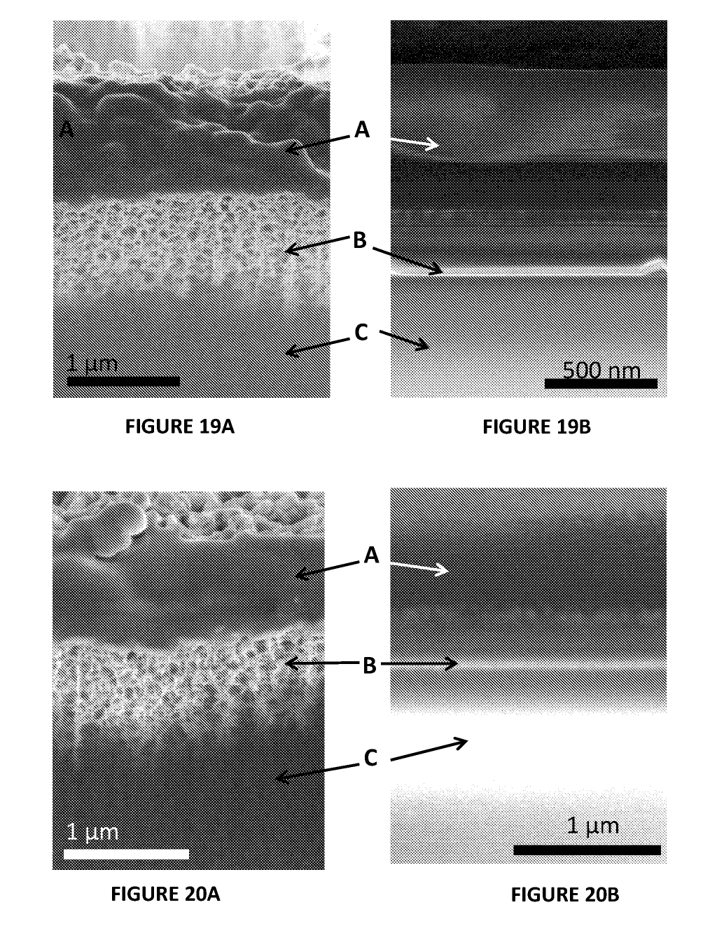

Results: under identical fabrication conditions, the final thickness of the resulted gold nanoporous network which was grown on top of silica aerogel substrate was ˜1 μm (FIG. 19A), pronouncedly larger than the dense gold film which was grown on top of a glass slide, ˜40 nm (FIG. 19B). Similarly, in the case of silver, the network which was grown on silica aerogel substrate gave rise to a thickness of ˜1 μm (FIG. 20A), whereas the silver film formed on top of the glass slide gave rise to a thickness of ˜35-45 nm (FIG. 20B).

### Example 13—Linear Optic Properties of Metal-Based Nanoporous Films

The following samples were prepared according to the same procedures of Example 12:

A) ˜1 μm thick gold nanoporous film on silica aerogel substrate;

B) ˜40 nm thick dense gold film on a glass slide substrate;

C) ˜350 nm thick silver nanoporous film on silica aerogel substrate; and

D) 25 nm thick silver film on a glass slide substrate.

The light transmittance of the samples was measured in the range of 450-700 nm.

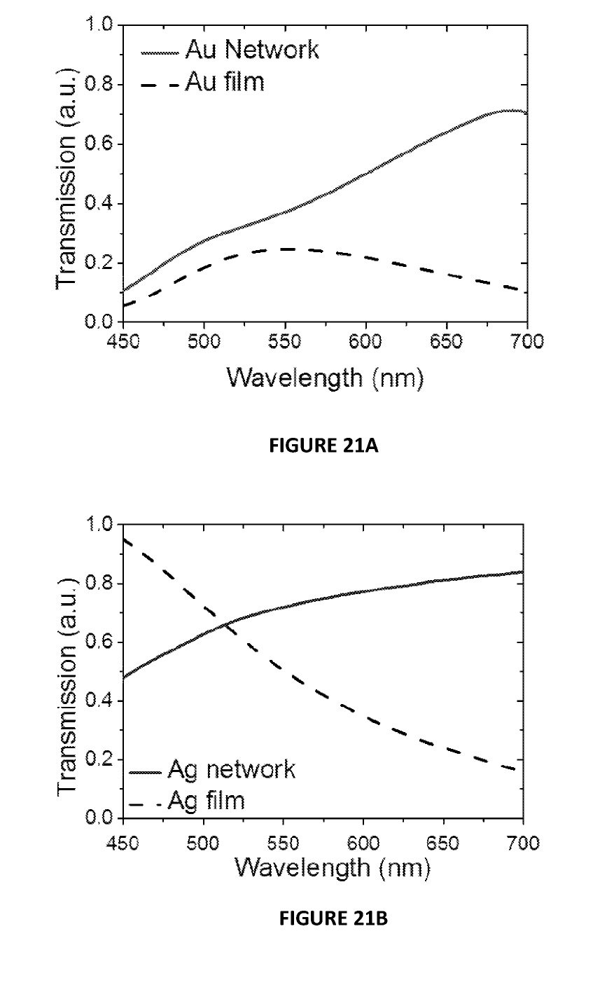

According to the transmission spectra, both gold nanoporous network and dense film demonstrate the interband transition at about 510 nm. However, the gold network formed over silica aerogel demonstrate a broad optical transmission towards the near infra-red regime, in contrast to the low transmission observed for the dense gold film obtained on top of the glass slide (FIG. 21A). In the case of silver, the network formed over silica aerogel demonstrated a light transmission increase while increasing the wavelength (lower frequencies), and an opposite effect was detected for the film obtained on top of the glass slide showing a decreased light transmission with increasing wavelength (FIG. 21B).

### Example 14—Preparation of Hydrophobic Silica Aerogel Substrates

In order to prepare hydrophobic silica aerogel substrates, alcogels were prepared as described hereinabove as Example 1. Then, their pore-content was gradually replaced as a preparative procedure for immersion in a silane solution as described herein below. The gradual pore-content replacement was aimed at avoiding damaging the delicate alcogel nanostructure, by preventing the gel from shrinking or cracking due to contraction, while polar-to-non-polar solvent exchange.

By the end of the overnight suspension in anhydrous ethanol, the alcogels were transferred into a 50:50 vol % solution of anhydrous hexane (Sigma Aldrich) and ethanol, in which they were suspended overnight. Then, they were suspended for a day in 100 vol % hexane. Afterwards, a solution of 5 wt % trimethylchlorosilane (TMCS, Sigma Aldrich) in hexane was prepared, in which the alcogels were suspended under mild heating (45° C.) for 3 hours. The heating aimed at casing the TMCS to react with the hydroxyl groups that line the solid framework of the silica gel to replace them with non-polar trimethylsilyl groups. The alcogel were suspended in the last solution for additional 3 days under ambient conditions. The pore content was replaced again into 100 vol % ethanol in a symmetrical and gradual fashion (using a step of 50:50 vol % anhydrous hexane and ethanol) as before. The second pore content replacement used as a preparative step for the subsequent superdrying process, in which the pore content was further gradually replaced by liquid CO₂.

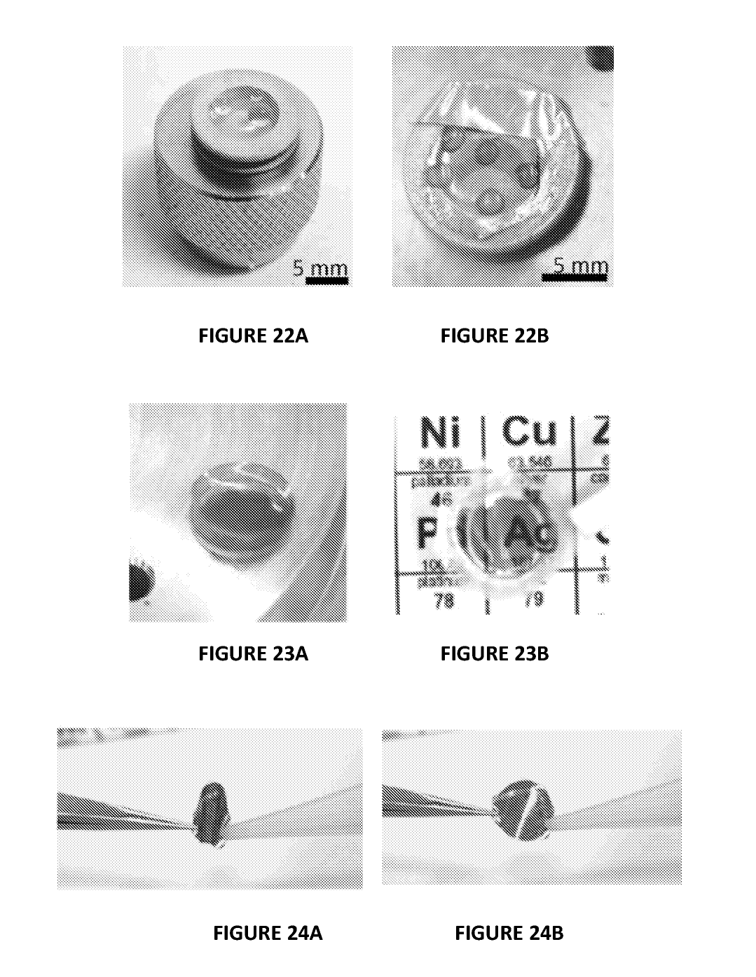

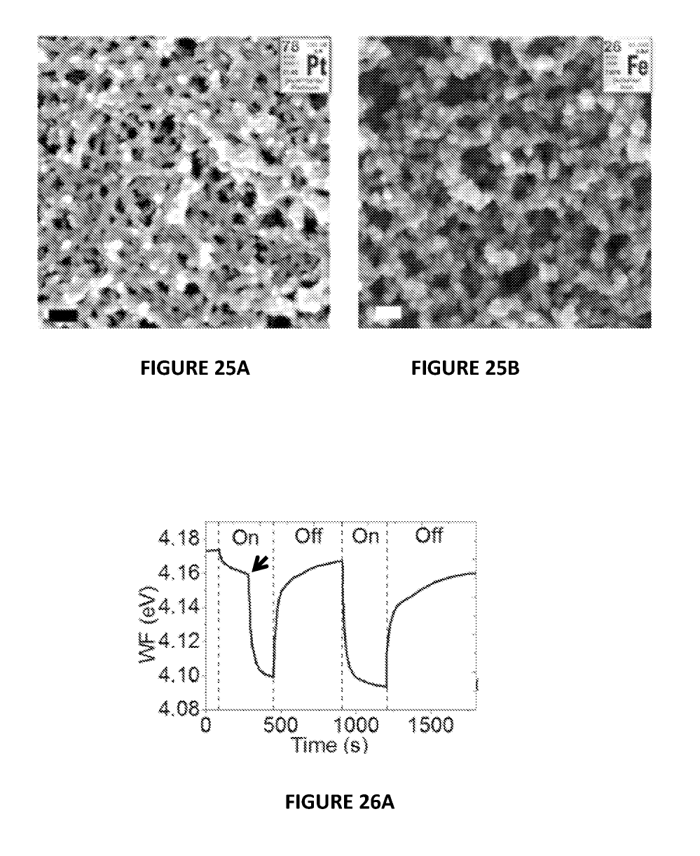

The resulted silica aerogel demonstrated hydrophobic characteristics. Upon applying water droplets, neutral pH, acidic or basic on the surface of modified silica aerogel (comprising the silane molecules), a high contact angle was observed between the liquid and silica surface (FIG. 22A). Furthermore, after depositing silver over the hydrophobic silica aerogels as described hereinabove Example 3, where the sputtering time was 90 seconds, the hydrophobic nature of the formed silver networks appeared to be hydrophobic as well (FIG. 22B).

### Example 15—Electrostatic Nature of Silica Aerogel Substrates

In order to demonstrate the electrostatic character of the silica aerogel substrates, an aerogel as prepared in Example 14 was placed in close proximity to tweezers made of polytetrafluoroethylene (PTFE), which is known to be electrostatic. The disc-shaped silica aerogel immediately stuck to the tweezers' surface due to electrostatic interactions.

### Example 16—Network Delamination and Flexibility

The process for the preparation of a hydrophobic silica surface as described hereinabove (Example 14) allows a unique separation of the nanoporous metal-based film from the hydrophonic silica aerogel support. The delamination of the nanoporous metal-based film was carried using a tape, which was attached to the hydrophobic silica substrate from the bottom end (not touching the metal surface) and was later gently pulled to release the nanoporous metal-based film (FIGS. 23A and 23B). The free film demonstrated mechanical stability and flexibility, as it was folded between to tweezers and then released. The free metal film regained its original structure after the folding (FIG. 24A before folding and 24B after folding).

### Example 17—Preparation of Nanoporous Networks from Different Materials

Ti and Fe networks were prepared by sputtering using an argon beam with an energy of 10 keV and an intensity of 614 μA. The background pressure was kept under 1×10⁻⁴ Torr during the sputtering deposition. The deposition time was 2 minutes.

### Example 18—Photoelectric Activity of Gold and Silver-Based Nanoporpous Films

A) The response of gold and silver-based nanoporpous films to white light was measured using a contact potential difference (CPD) measurement utilizing a macroscopic Kelvin probe apparatus under different light conditions: i) 40 W; and ii) 80 W (halogen).

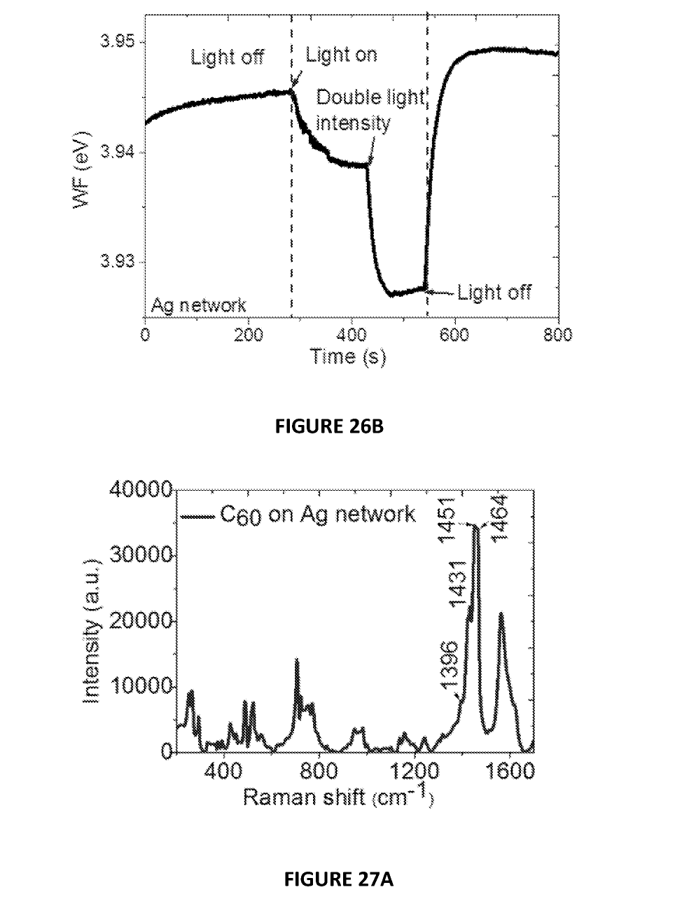

Results: according to the measurements, a detectable decrease in the work function (WF) value is revealed under moderate illumination power and a further decrease in the WF values was detected as the illumination power was increased (FIG. 26). The arrow in FIG. 26 represents a point where the light intensity was doubled during the experiment. The measured decrease suggests that under white light illumination conditions a large number of hot-electrons are generated in the three dimensional metallic networks, and can be further used for carrying out chemical reactions.

B) The ability of silver-based nanoporpous films to chemically reduce C₆₀ molecules was measured utilizing surface enhanced Raman scattering (SERS). A sample of silver-based nanoporpous film was prepared as described in Example 12, and an additional 20 nm thick layer of C₆₀ was deposited. This sample was prepared simultaneously with another C₆₀ layer sample deposited on a clean glass-slide. The deposition was carried utilizing a vacuum thermal evaporation system, and the thickness and deposition rate were monitored and maintained using an Inficon SQC310-C rate controller and quartz crystal monitors. The base pressure of the evaporator was 3×10⁻⁷ Torr. The effect of silver-based porous film as a surface-enhance Raman scattering (SERS) substrate was measured using a Raman microscope (HORIBA Scientific LabRAM HR). Raman spectra were recorded employing a laser excitation wavelength at 532 nm with 60 mW power, at room temperature. As an experimental control, Raman spectra of a dense Ag film prepared on glass-slide with C₆₀ molecules on top of the silver's surface was measured.

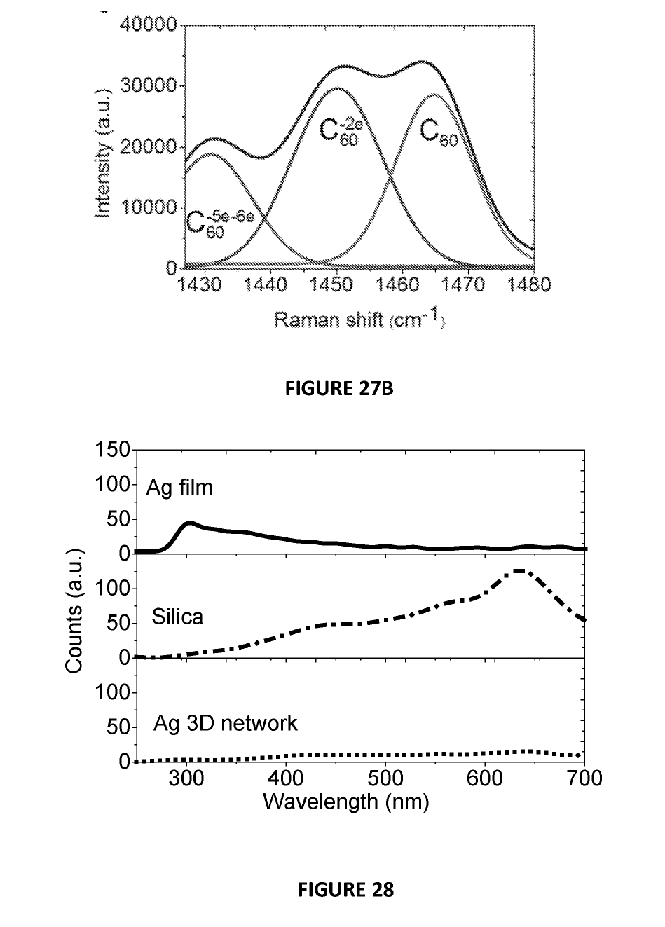

Results: a shift of the pentagonal band A_{g}(2) at 1464 cm⁻¹ to a lower frequency bands at 1451 and 1431 cm⁻¹, was observed and is attributed to the anion radical of C₆₀ (FIG. 27A). From the deconvoluted pentagonal band A_{g}(2) it can be detected that a fraction of the C₆₀ molecules deposited on the silver surface experienced charge transfer of 2 electrons and another fraction was reduced by ˜5-6 electrons (FIG. 27B). The intensity ratio between the soft (1451 and 1431 cm⁻¹) and hard (1464 cm⁻¹) A_{g}(2) bands suggests that ˜40% of the C₆₀ molecules undergo a two-electron reduction process, whereas ˜25% of them undergo a 5-6 electron reduction.

C) Cathodoluminescence (CL) imaging and spectroscopy of surface plasmon (SP) were carried to measure the decay modes of SP in a silver-based nanoporous film. A sample prepared as indicated in Example 12 was used for the measurement. According to the small CL signal obtained from the silver network's surface, it appears that there is no photon emission from the network, which suggests that a non-radiative decay of SPs modes into hot-electrons takes place. These hot-electrons can be further used for conducting chemical transformations supported by these silver networks. A comparison was made between the silver-based nanoporos film, a dense silver film (prepared as described in Example 12) and a bare silica aerogel substrate showed that almost no CL signal was obtained from the silver network (FIG. 28).

### Example 19—Preparation of ZnO Networks

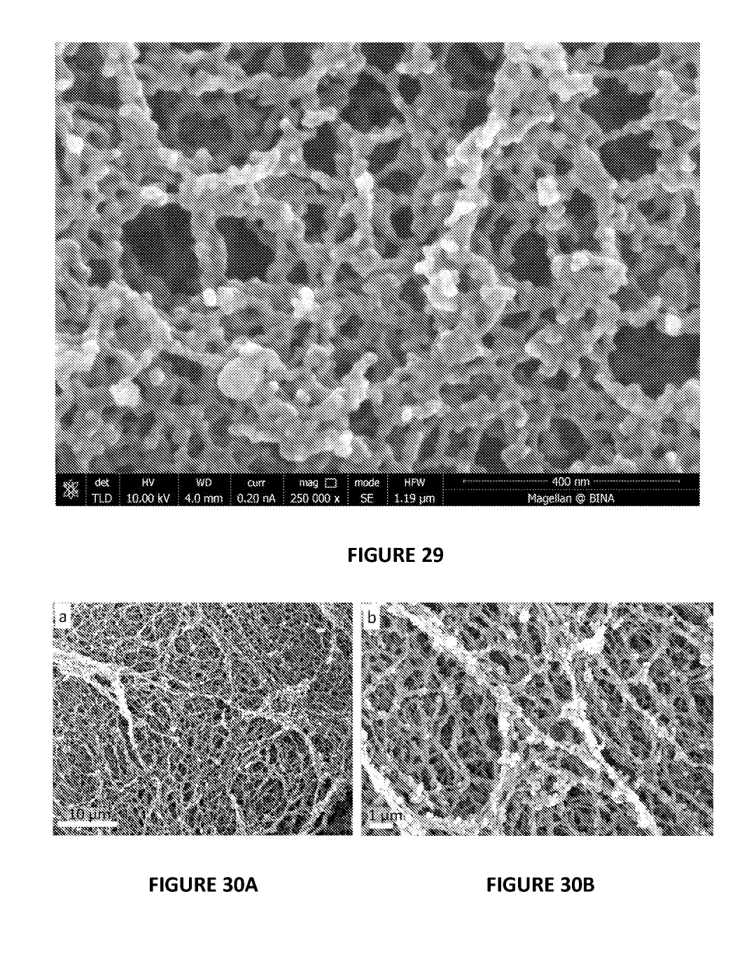

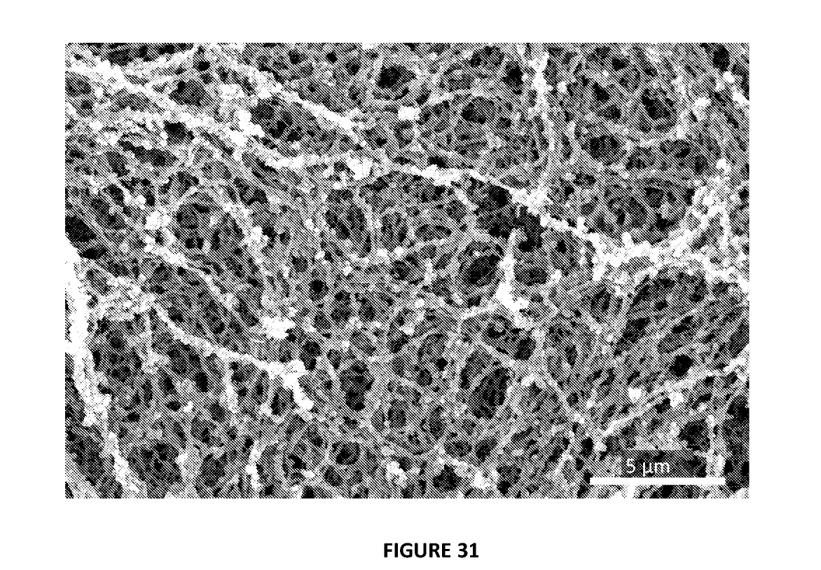

ZnO networks (FIG. 29) were prepared by sputtering using an argon beam with an energy of 10 keV and an intensity of 614 μA. The background pressure is kept <1×10-4 Torr during the sputtering deposition. The deposition time was 4 min.

TABLE 6
GATAN sputtering parameters

| Chamber pressure | <1 × 10⁻⁴ | Torr |
|---|---|---|
| Beam energy | 10 | keV |
| time | 4 | min |
| Gas | Ar | |
| Current | 614 | μA |

### Example 20—TiO₇-Based Nonporous Film

Of an additional major importance is the applicability of the technique for the preparation of NETAL-oxides, i.e. large-scale 3D nanoporous networks which are made of metal-oxides. For example, a Titania (TiO₂) NETAL is presented in the HR-SEM image in FIG. 30. The TiO₂ acquired a network morphology comprising pearl-like strings in the size range of ˜100-600 nm. Such networks can be exploited for catalytic applications. For instance, networked nanostructures of TiO₂ were demonstrated to plasmonically enhance visible-light water splitting when combined with gold nanoparticles.

TABLE 7
Sputtering parameters using the BESTEC instrument (TiO₂).

| | | |
|---|---|---|
| Stage rotation | 5 | rpm |
| Target distance from stage | 8 | cm |
| Gas flow | 2.7 | sccm |
| Working pressure | 5 × 10−6 | bar |
| Preliminary pressure | 5 × 10−10 | bar |

| | |
|---|---|
| Power | TiO₂: 200 W for RF plasma |
| | ignition, and 160 W for sputtering. |

It is appreciated by persons skilled in the art that the present invention is not limited by what has been particularly shown and described hereinabove. Rather the scope of the present invention includes both combinations and sub-combinations of various features described hereinabove as well as variations and modifications. Therefore, the invention is not to be constructed as restricted to the particularly described embodiments, and the scope and concept of the invention will be more readily understood by references to the claims, which follow.

1.-49. (canceled)

50. A method for the fabrication of a nanoporous metal-based film, the method comprising the steps of:
a) providing a ceramic aerogel substrate having a nanoporous structure, wherein the substrate comprises a bulk portion and a surface portion and wherein the surface portion is chemically or physically modified; and
b) depositing a metal or a metal oxide from a deposition source on the ceramic aerogel substrate by a physical vapor deposition (PVD) process, wherein the deposition is performed at a power of less than about 90 W or at a current ranging from about 0.5 mA to about 100 mA,
thereby obtaining a nanoporous metal-based film supported on the ceramic aerogel substrate.

51. The method according to claim 50, wherein the ceramic aerogel is formed from a material selected from the group consisting of a silicon dioxide (SiO₂), titanium dioxide (TiO₂), zirconium dioxide (ZrO₂), cadmium sulfide (CdS), cadmium selenide (CdSe), zirconium sulfide (ZnS), lead sulfide (PbS), and combinations thereof.

52. The method according to claim 50, wherein the chemically modified surface portion includes pores, wherein at least about 20% of the pore volume is filled with gaseous molecules or atoms, and wherein the ceramic aerogel substrate comprises less than about 5% of adsorbed water or water vapor relatively to the total weight of the aerogel.

53. The method according to claim 50, wherein the ceramic aerogel substrate has a mean pore size ranging from about 2 nm to about 50 nm.

54. The method according to claim 50, wherein the step of providing the aerogel comprises a step of preparing an alcogel by a sol-gel process under a supersaturated alcoholic vapor atmosphere for about 15 minutes; and an alcogel suspension step comprising holding the alcogel under a substantially anhydrous liquid for about 12 hours.

55. The method according to claim 54, wherein the step of providing the aerogel further comprises supercritical drying of the alcogel, comprising placing the alcogel into a critical point dryer (CPD) tank, which is substantially free of alcohol, wherein the alcogel comprises a layer of the substantially anhydrous liquid on at least one surface thereof.

56. The method according to claim 55, wherein the deposition of the metal is initiated within less than about 30 minutes from the termination of the supercritical drying step.

57. The method according to claim 50, wherein the step of providing the ceramic aerogel substrate comprises etching of the surface portion of the aerogel or adsorption of organic molecules on the surface portion of the ceramic aerogel substrate, the bulk portion of the ceramic aerogel substrate or both.

58. The method according to claim 57, wherein the organic molecules are selected from the group consisting of alkyls, organothiols, organosilanes, and combinations thereof.

59. The method according to claim 50, wherein the metal is selected from the group consisting of Au, Ag, Pt, Al, Cu, Fe and Ti or wherein the metal comprises a metal alloy, selected from the group consisting of Au/Ag, Au/Cu, Au/Ag/Cu, Au/Al, Au/Pt, Au/Ti, Au/Fe, Au/Ag/Al, Au/Ag/Cu/Pt, Au/Ag/Cu/Al, Au/Ag/Cu/Ti, Pt/Ag, Pt/Cu, Cu/Al, Cu/Ag, Pt/Fe, Pt/Al, Pt/Ag/Cu, Pt/Au/Cu/Ti, Ag/Fe, Cu/Fe, Ti/Fe, and Pt/Au/Al.

60. The method according to claim 50, wherein the metal oxide is selected from the group consisting of CuO, CuO₂, AgO, AgO₂, TiO₂, Al₂O₃, and combinations thereof.

61. The method according to claim 50, wherein the PVD process is a sputter deposition, wherein the deposition source comprises a plasma source and a metal target and wherein the plasma source operates at a power of lower than about 90 W during the deposition step and wherein the sputter deposition continues for up to about 10 minutes.

62. The method according to claim 50, wherein the PVD process is an evaporative deposition, and wherein the deposition source comprises a metal or a metal oxide source and an energy source and wherein the energy source operates at a current of from about 1 mA to about 100 mA during the deposition step.

63. The method according to claim 50, further comprising a step of separating the metal-based film from the ceramic aerogel substrate, performed by dry etching, wet chemical etching, cutting, peeling or any combination thereof.

64. A nanoporous metal-based film, prepared according to the method of claim 63.

65. A nanoporous metal-based film supported on a ceramic aerogel substrate having a nanoporous structure and an electrostatic surface, wherein the nanoporous structure and the electrostatic surface of the aerogel define the nanoporous structure of the metal-based film.

66. The nanoporous metal-based film according to claim 65, wherein the metal-based film has a purity of at least about 98% wt.

67. The nanoporous metal-based film according to claim 65, wherein the ceramic aerogel is formed from a material selected from the group consisting of a silicon dioxide (SiO₂), titanium dioxide (TiO₂), zirconium dioxide (ZrO₂), cadmium sulfide (CdS), cadmium selenide (CdSe), zirconium sulfide (ZnS), lead sulfide (PbS), and combinations thereof.

68. The nanoporous metal-based film according to claim 65, wherein the ceramic aerogel substrate has a mean pore size ranging from about 2 nm to about 50 nm and the nanoporous metal-based film has a mean pore size ranging from about 50 nm to about 500 nm.

69. The nanoporous metal-based film according to claim 65, comprising a metal selected from the group consisting of Au, Ag, Pt, Al, Cu, Fe and Ti, a metal alloy, selected from the group consisting of Au/Ag, Au/Fe, Au/Cu, Au/Ag/Cu, Au/Al, Au/Pt, Au/Ti, Au/Ag/Al, Au/Ag/Cu/Pt, Au/Ag/Cu/Al, Au/Ag/Cu/Ti, Pt/Ag, Pt/Cu, Cu/Al, Cu/Ag, Pt/Fe, Pt/Al, Pt/Ag/Cu, Pt/Au/Cu/Ti, Ag/Fe, Cu/Fe, Ti/Fe and Pt/Au/Al, or a metal oxide selected from the group consisting of CuO, CuO₂, AgO, AgO₂, TiO₂, Al₂O₃, and combinations thereof.

70. The nanoporous metal-based film according to claim 65, being transparent in the visible, near-IR and ultra-violet (UV) spectra region.
